(19) United States
(12) Patent Application Publication
(10) Pub. No.: US 2025/0273559 A1
(43) Pub. Date: Aug. 28, 2025

(54) CENTER-CONNECTION BONDED MEMORY ASSEMBLY AND METHODS FOR FORMING THE SAME

(71) Applicant: SANDISK TECHNOLOGIES LLC, ADDISON, TX (US)

(72) Inventors: Yusuke IKAWA, Yokkaichi (JP); Hiroyuki MIZUKOSHI, Yokkaichi (JP); Ryuji YAMASHITA, Yokkaichi (JP); Masaaki HIGASHITANI, Cupertino, CA (US)

(21) Appl. No.: 18/588,791

(22) Filed: Feb. 27, 2024

(51) Int. Cl. H01L 23/522; G11C 16/04; G11C 16/08; G11C 16/24; H01L 23/528; H10B 41/10; H10B 41/27; H10B 41/35; H10B 41/40; H10B 43/10; H10B 43/27; H10B 43/35; H10B 43/40

(52) U.S. Cl. CPC H01L 23/5226; G11C 16/0483; G11C 16/08; G11C 16/24; H01L 23/5283; H10B 41/10; H10B 41/27; H10B 41/35; H10B 41/40; H10B 43/10; H10B 43/27; H10B 43/35; H10B 43/40

(57) ABSTRACT

A bonded assembly includes a logic die and a memory die. The memory die includes an alternating stack of insulating layers and electrically conductive layers, memory-side dielectric material layers embedding memory-side metal interconnect structures and memory-side bonding pads, memory stack structures each comprising a memory film and a vertical semiconductor channel vertically extending through the alternating stack in a memory array region, layer contact via structures contacting a respective electrically conductive layer within the alternating stack in a contact region, a through-stack via structure vertically extending through a vertically-extending opening in the alternating stack within a center region of the memory die, and a backside conductive pad electrically contacting the a through-stack via structure. The logic die includes a peripheral circuit and logic-side bonding pads which are bonded to the memory-side bonding pads.

### FIELD

The present disclosure relates generally to the field of semiconductor devices, and particularly to a bonded memory assembly including center input/output pads and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a bonded assembly includes a logic die and a memory die. The memory die includes an alternating stack of insulating layers and electrically conductive layers, memory-side dielectric material layers embedding memory-side metal interconnect structures and memory-side bonding pads, memory stack structures each comprising a memory film and a vertical semiconductor channel vertically extending through the alternating stack in a memory array region, layer contact via structures contacting a respective electrically conductive layer within the alternating stack in a contact region, a through-stack via structure vertically extending through a vertically-extending opening in the alternating stack within a center region of the memory die, which is a volume within the memory die that is more proximal to a geometrical center of the memory die than to a periphery of the memory die defined by outer sidewalls of the memory die in a plan view along a vertical direction, and a backside conductive pad electrically contacting the through-stack via structure. The logic die includes a peripheral circuit and logic-side bonding pads which are bonded to the memory-side bonding pads.

According to another aspect of the present disclosure, a method of forming a bonded assembly includes forming an alternating stack of insulating layers and electrically conductive layers over a carrier substrate; forming memory openings vertically extending through the alternating stack; forming memory stack structures in the memory openings, wherein each of the memory stack structures comprises a memory film and vertical semiconductor channel; forming a vertically-extending opening through the alternating stack; forming a through-stack via structure in the vertically-extending opening; forming memory-side dielectric material layers embedding memory-side metal interconnect structures and memory-side bonding pads over the alternating stack and the through-stack via structure form a memory die; providing a logic die which comprises peripheral circuit and logic-side bonding pads; bonding the logic-side bonding pads to the memory-side bonding pads; detaching the carrier substrate from an assembly comprising the memory die and the logic die to expose the through-stack via structure; and forming a backside conductive pad that is electrically connected to the through-stack via structure.

### BRIEF DESCRIPTION OF THE DRAWINGS

FIG. 1 is a schematic vertical cross-sectional view of an exemplary structure for forming a memory die after formation of a backside dielectric layer, in-process source-level material layers, an alternating stack of insulating layers and sacrificial material layers having stepped surfaces, and a retro-stepped dielectric material portion over a carrier substrate according to an embodiment of the present disclosure.

FIG. 2A is a schematic vertical cross-sectional view of the exemplary structure after forming memory openings according to an embodiment of the present disclosure.

FIG. 2B is a top-down view of the exemplary structure of FIG. 2A. The vertical plane A-A′ is the cut plane of the vertical cross-sectional view of FIG. 2A.

FIG. 2C is a top-down view of an in-process memory die including the exemplary structure at the processing steps of FIGS. 2A and 2B.

FIGS. 3A-3D are sequential vertical cross-sectional views of a memory opening during formation of a memory opening fill structure according to an embodiments of the present disclosure.

FIG. 4 is a vertical cross-sectional view of the exemplary structure after formation of memory opening fill structures according to an embodiment of the present disclosure.

FIG. 5A is a vertical cross-sectional view of the exemplary structure after formation of a contact-level dielectric layer, a patterned hard mask layer, lateral isolation trenches, and discrete through-stack openings according to an embodiment of the present disclosure.

FIG. 5B is a top-down view of the exemplary structure of FIG. 5A. The vertical plane A-A′ is the cut plane of the vertical cross-sectional view of FIG. 5A.

FIG. 5C is a top-down view of an in-process memory die including the exemplary structure at the processing steps of FIGS. 2A and 2B.

FIG. 6 is a vertical cross-sectional view of the exemplary structure after vertical extension of the discrete through-stack openings according to an embodiment of the present disclosure.

FIG. 7 is a vertical cross-sectional view of the exemplary structure after formation of sacrificial lateral isolation trench fill structures and sacrificial through-stack opening fill structures according to an embodiment of the present disclosure.

FIG. 8 is a vertical cross-sectional view of the exemplary structure after removal of the sacrificial lateral isolation trench fill structures according to an embodiment of the present disclosure.

FIG. 9 is a vertical cross-sectional view of the exemplary structure after formation of a source cavity according to an embodiment of the present disclosure.

FIG. 10 is a vertical cross-sectional view of the exemplary structure after formation of a source contact layer and dielectric capping liners according to an embodiment of the present disclosure.

FIG. 11 is a vertical cross-sectional view of the exemplary structure after formation of laterally-extending cavities according to an embodiment of the present disclosure.

FIG. 12 is a vertical cross-sectional view of the exemplary structure after formation of electrically conductive layers according to an embodiment of the present disclosure.

FIG. 13 is a vertical cross-sectional view of the exemplary structure after formation of lateral isolation trench fill structures and contact via structures according to an embodiment of the present disclosure.

FIG. 14 is a vertical cross-sectional view of the exemplary structure after removal of the sacrificial through-stack opening fill structures according to an embodiment of the present disclosure.

FIG. 15 is a vertical cross-sectional view of the exemplary structure after formation of tubular dielectric spacers and through-stack via structures according to an embodiment of the present disclosure.

FIG. 16 is a vertical cross-sectional view of the exemplary structure after formation of layer contact via structures, drain contact via structures, and peripheral connection via structures according to an embodiment of the present disclosure.

FIG. 17 is a vertical cross-sectional view of the exemplary structure after formation of a memory die according to an embodiment of the present disclosure.

FIG. 18 is a vertical cross-sectional view of the exemplary structure after formation of a bonded assembly of the memory die and a logic die according to an embodiment of the present disclosure.

FIG. 19 is a vertical cross-sectional view of the exemplary structure after optional removal of a carrier substrate from the memory die according to an embodiment of the present disclosure.

FIG. 20 is a vertical cross-sectional view of the exemplary structure after formation of backside via openings according to an embodiment of the present disclosure.

FIG. 21 is a vertical cross-sectional view of the exemplary structure after formation of source layers and metal pads according to an embodiment of the present disclosure.

FIG. 22A is a vertical cross-sectional view of the exemplary structure after formation of a backside passivation layer and openings therethrough according to an embodiment of the present disclosure.

FIG. 22B is a top-down view of the exemplary structure of FIG. 22A.

FIG. 23A is a vertical cross-sectional view of an alternative configuration of the exemplary structure after formation of bonding pads therethrough according to an embodiment of the present disclosure.

FIG. 23B is a top-down view of the exemplary structure of FIG. 23A.

FIG. 24 is a vertical cross-sectional view of an assembly of a logic die and two memory dies according to an embodiment of the present disclosure.

### DETAILED DESCRIPTION

As discussed above, the embodiments of the present disclosure are directed to a bonded memory assembly including center input/output pads and methods for manufacturing the same, the various aspects of which are described below. Embodiments of the disclosure can be employed to form various structures including a multilevel memory structure, non-limiting examples of which include semiconductor devices such as three-dimensional memory array devices comprising a plurality of memory strings.

The embodiments of the present disclosure are directed to a center-connection chip bonding area structure, in which external bonding pad (such as solder bonding pad or wire bonding pad) is positioned in a center region of a backside of a memory die over the memory array. The external bonding pad is connected to input/output driver circuit in a logic die using a through-stack via structure that vertically extends through alternating stacks of insulating layers and electrically conductive layers in a memory die, which is bonded to the logic die. Direct links between the external bonding pads the input/output drivers enhances the speed of operation of the bonded assembly including the logic die and the memory die by consolidating external electrical connections around a center region of the logic die, and also permits elimination of a dedicated input/output peripheral area in the memory die, which increases the density of the memory devices.

At least one electrically conductive layer can be deposited on the backside of the memory die after removal of a carrier substrate. The at least one electrically conductive layer can be patterned into electrically conductive source layers and conductive backside pads. In one configuration, the backside pads may be employed as the external bonding pads. Alternatively, a bonding-level dielectric layer embedding patterned conductive structures can be formed over the backside pads. In this case, the patterned conductive structures can include bonding pads configured for metal-to-metal bonding, and an additional memory die may be bonded to the memory die. In this case, a subset of the bonding pads may be employed as paths for connecting to external bonding pads within the additional memory die.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

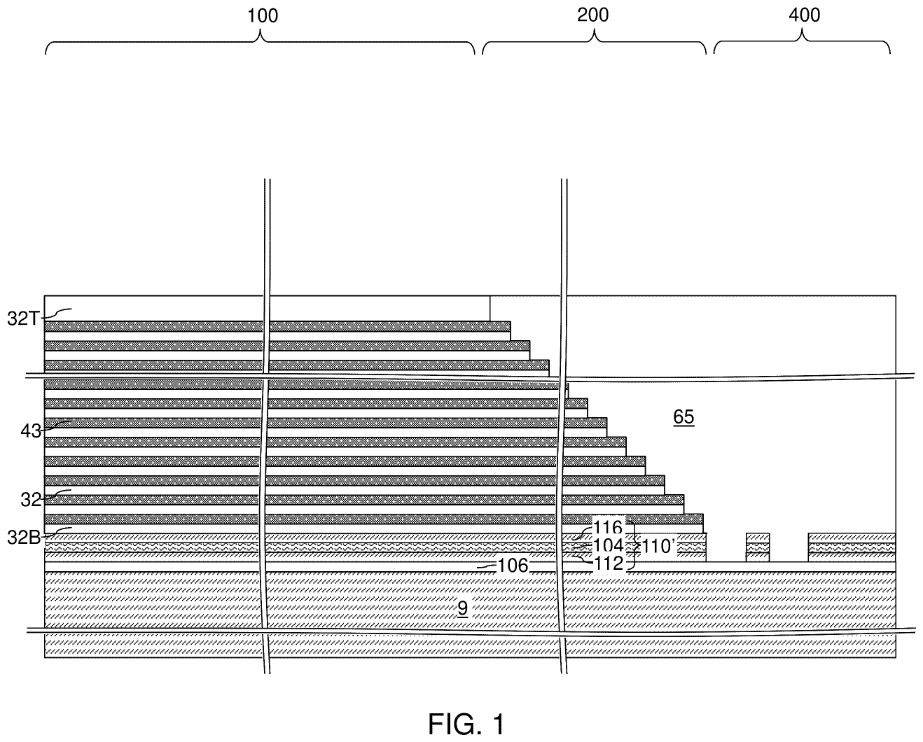

Referring to FIG. 1, an exemplary structure according to an embodiment of the present disclosure is illustrated. The exemplary structure comprises a carrier substrate 9, which may be a semiconductor substrate, a dielectric substrate, or a conductive substrate. For example, the carrier substrate 9 may comprise a commercially available silicon wafer. Alternatively, the carrier substrate 9 may comprise any material that may be removed selective the materials of a backside dielectric layer 106 and a retro-stepped dielectric material portion 65 to be subsequently formed.

A dielectric material layer can be formed on a top surface of the carrier substrate 9. The dielectric material layer can be subsequently employed as a stopping material layer for a process that removes the carrier substrate 9, and is herein referred to as a backside dielectric layer 106, or as a stopper dielectric layer. If a polishing process such as a chemical mechanical polishing process is employed to subsequently remove the carrier substrate 9, the backside dielectric layer 106 may be subsequently employed as a polishing stopper material layer. If an etch process such as a wet etch process is employed to subsequently remove the carrier substrate 9, the backside dielectric layer 106 may be subsequently employed as an etch stop material layer. In one embodiment, the backside dielectric layer 106 comprises a dielectric material such as undoped silicate glass, a doped silicate glass, or silicon nitride. The thickness of the backside dielectric layer 106 may be in a range from 50 nm to 600 nm, such as from 100 nm to 300 nm, although lesser and greater thicknesses may also be employed.

In-process source-level material layers 110′ can be formed over the backside dielectric layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner (or selective to the lower source-level semiconductor layer 112) and the upper sacrificial liner (or selective to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

An alternating stack of first material layers and second material layers can be formed over the in-process source-level material layers 110′. In an alternative embodiment, the in-process source-level material layers 110′ and the backside dielectric layer 106 may be omitted, and the alternating stack is formed directly on a surface of the semiconductor substrate 9. In the alternating stack, the first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about twice the thickness of other insulating layers 32.

Stepped surfaces are formed in a contact region 200. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

The exemplary structure comprises a memory array region 100 in which each layer within the alternating stack (32, 42) is present and in which a three-dimensional array of memory elements is to be subsequently formed, the contact region 200 which contains the stepped surfaces of the alternating stack (32, 42) and in which layer contact via structures contacting word lines are to be subsequently formed, and a peripheral region 400 in which the layers within the alternating stack (32, 42) are absent. The peripheral region 400 may comprise a kerf region through which the memory dies will be diced and an edge seal region. Openings may be formed through the in-process source-level material layers 110′ in the peripheral region 400 for formation of edge seal structures.

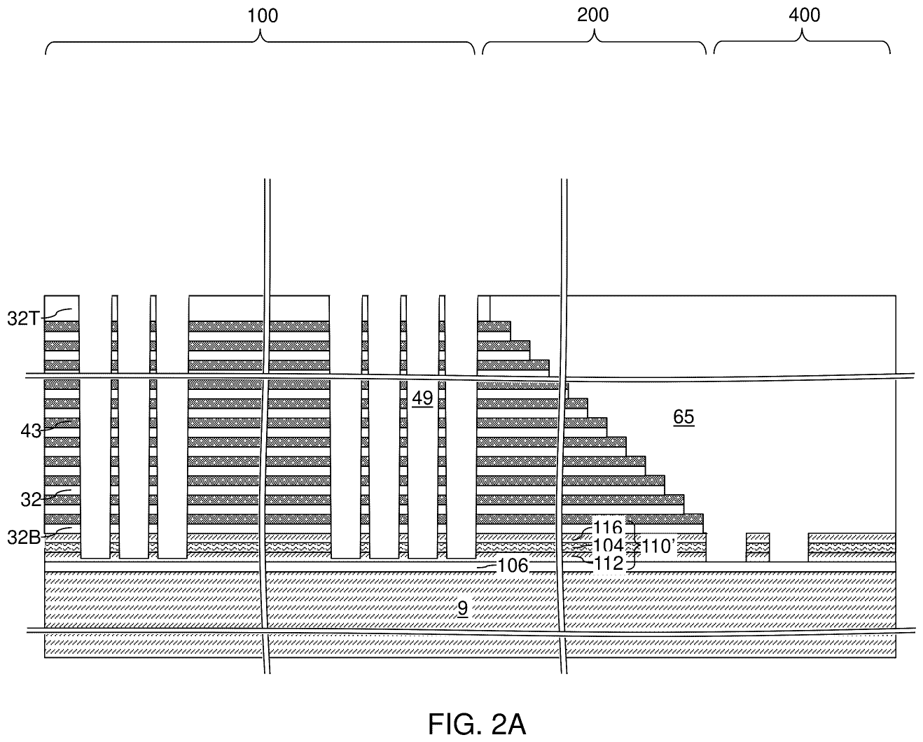

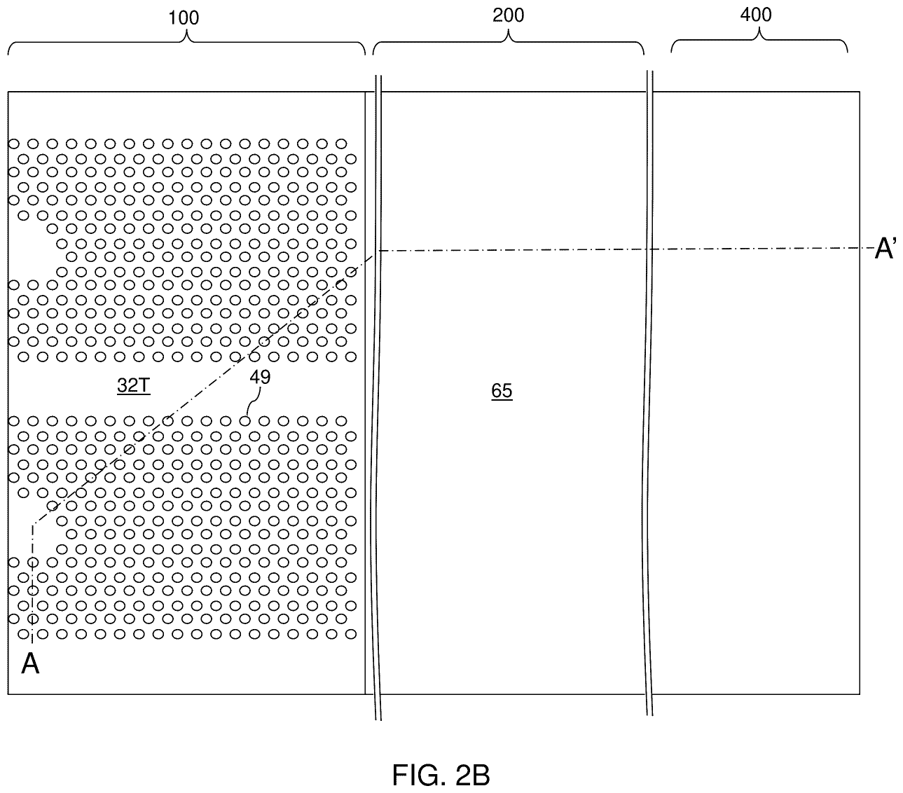

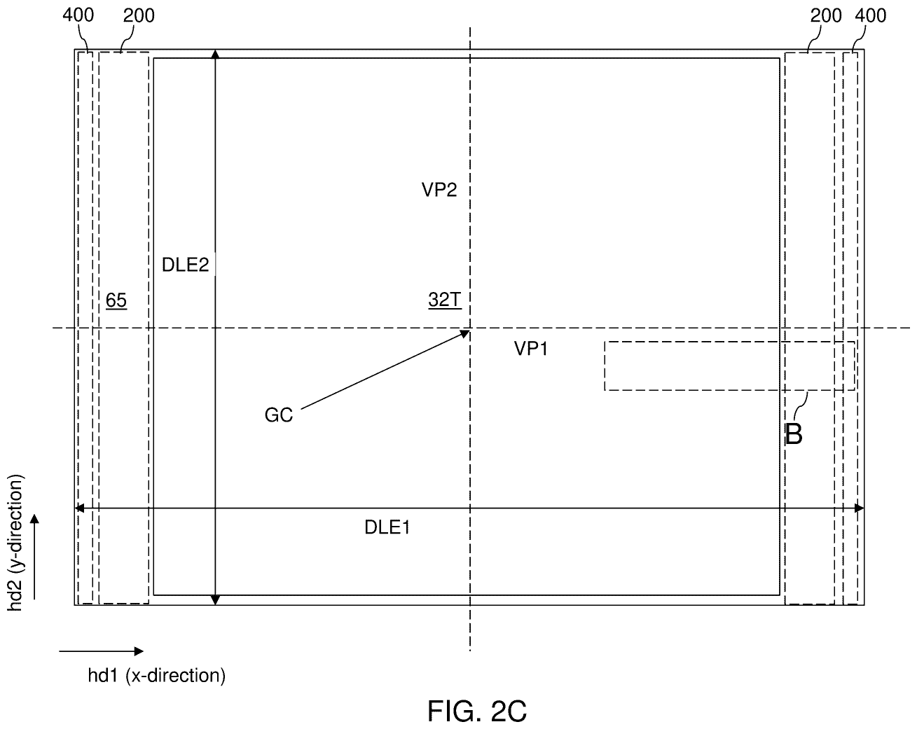

Referring to FIGS. 2A-2C, various views of the exemplary structure are illustrated after formation of memory openings 49. FIG. 2C is a top-down view of the exemplary structure that illustrates an entire area of an in-process memory die. FIG. 2B is a top-down view of region B of the top-down view of the exemplary structure shown in FIG. 2C. FIG. 2A is a vertical cross-sectional view of the exemplary structure along the vertical plane A-A′ of FIG. 2B. The in-process memory die may have a rectangular shape in a plan view, such as the top-down view of FIG. 2C. In one embodiment, the in-process memory die may have a first lateral dimension DLE1 (i.e., a first lateral extent) along a first horizontal direction (e.g., word line direction) hd1, which is also referred to as an x-direction of a Cartesian coordinate system representing locations within the in-process memory die. The in-process memory die may have a second lateral dimension DLE2 (i.e., a second lateral extent) along a second horizontal direction (e.g., bit line direction) hd2, which is also referred to as a y-direction of the Cartesian coordinate system. The geometrical center GC of the in-process memory die, a first vertical plane VP1 that bisects the in-process memory die and is parallel to the first horizontal direction hd1, and a second vertical plane VP2 that bisects the in-process memory die and is parallel to the second horizontal direction hd2 are also illustrated in FIG. 2C.

Specifically, an etch mask layer (not shown) can be formed over the alternating stack (32, 42) and the retro-stepped dielectric material portion 65, and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings (not illustrated) that are formed in the contact region 200. Each of the memory openings 49 and the support openings can vertically extend through the alternating stack (32, 42) and into the in-process source-level material layers 110′ In one embodiment, bottom surfaces of the memory openings 49 and the support openings may be formed within the lower source-level semiconductor layer 112 or at an interface between the lower source-level semiconductor layer and the backside dielectric layer 106.

The support openings may have a diameter in a range from 60 nm to 400 nm, such as from 120 nm to 300 nm, although lesser and greater thicknesses may be employed. The memory openings 49 may have a diameter in a range from 60 nm to 400 nm, such as from 120 nm to 300 nm, although lesser and greater thicknesses may be employed.

In one embodiment, the memory array region 100 may be laterally spaced apart from the contact region 200 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2.

Sacrificial memory opening fill structures (not shown) can be formed in the memory openings 49. The sacrificial memory opening fill structures may comprise a carbon-based material (such as amorphous carbon or diamond-like carbon), a semiconductor material (such as amorphous silicon or polysilicon), a dielectric fill material (such as borosilicate glass or organosilicate glass), or a polymer material. A dielectric fill material can be deposited in the support openings to form support pillar structures (not shown). The sacrificial memory opening fill structures can be subsequently removed to form cavities in the memory openings 49.

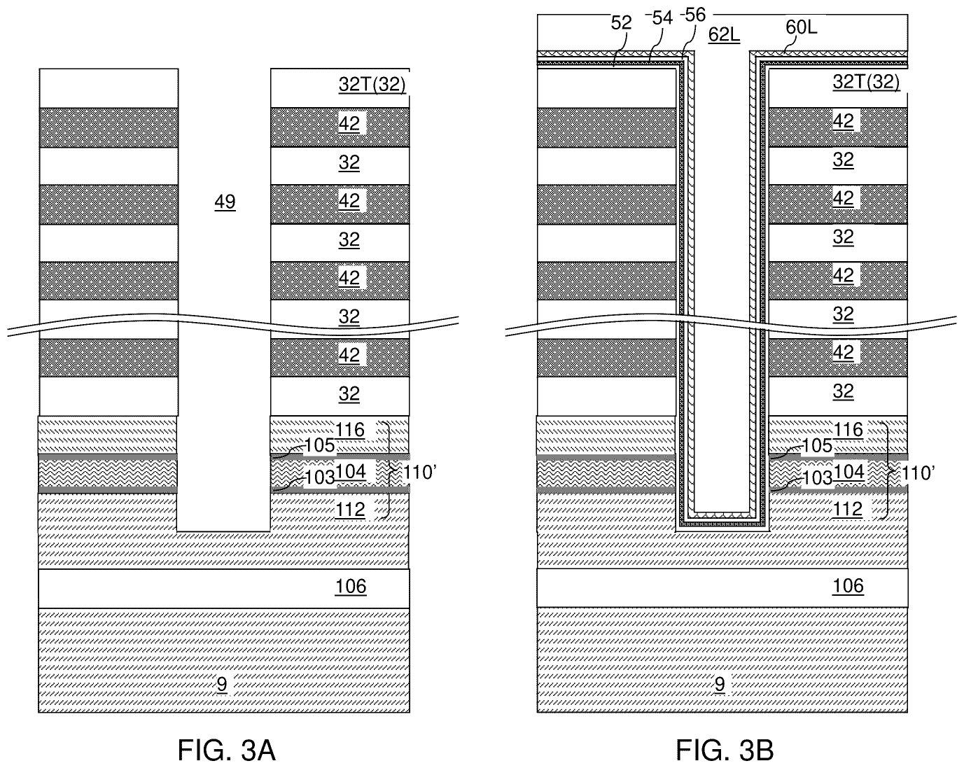

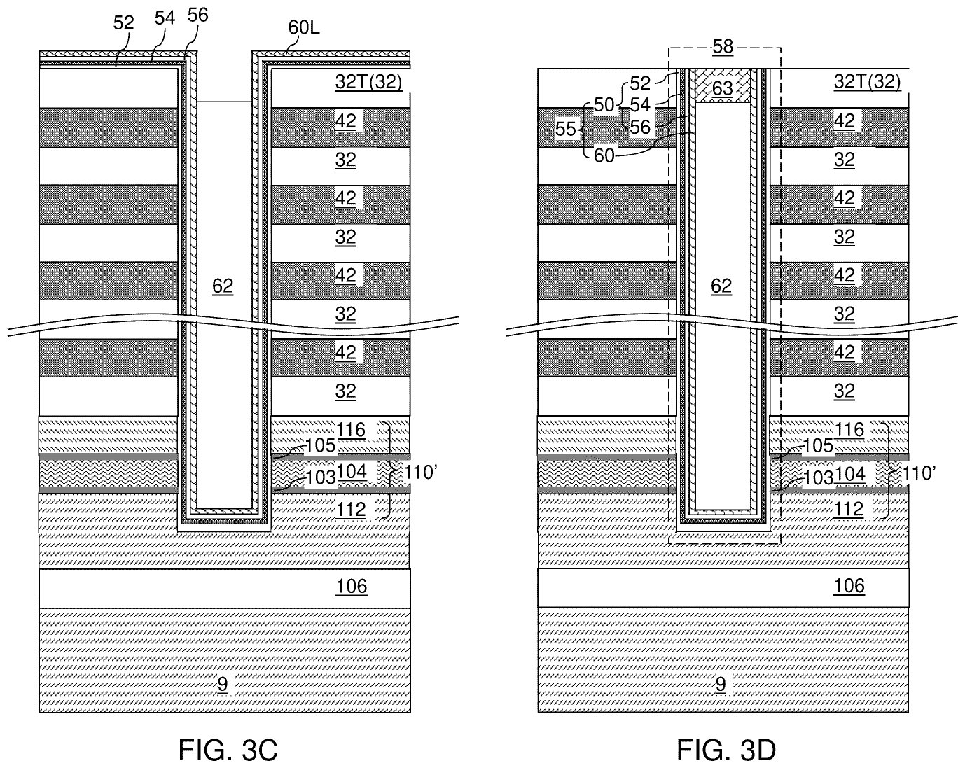

FIGS. 3A-3D are sequential vertical cross-sectional views of a memory opening 49 during formation of a NAND string (e.g., a dummy NAND string or a data storage NAND string) which is referred to below as a “memory opening fill structure” 58 according to an embodiment of the present disclosure.

Referring to FIG. 3A, a memory opening 49 is illustrated after the processing steps of FIGS. 2A-2C.

Referring to FIG. 3B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride). In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 3C, the dielectric core layer 62L can be vertically recessed such that each remaining portion of the dielectric core layer 62L has a top surface at, or about, the horizontal plane including the bottom surface of the topmost insulating layer 32T. Each remaining portion of the dielectric core layer 62L constitutes a dielectric core 62.

Referring to FIG. 3D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

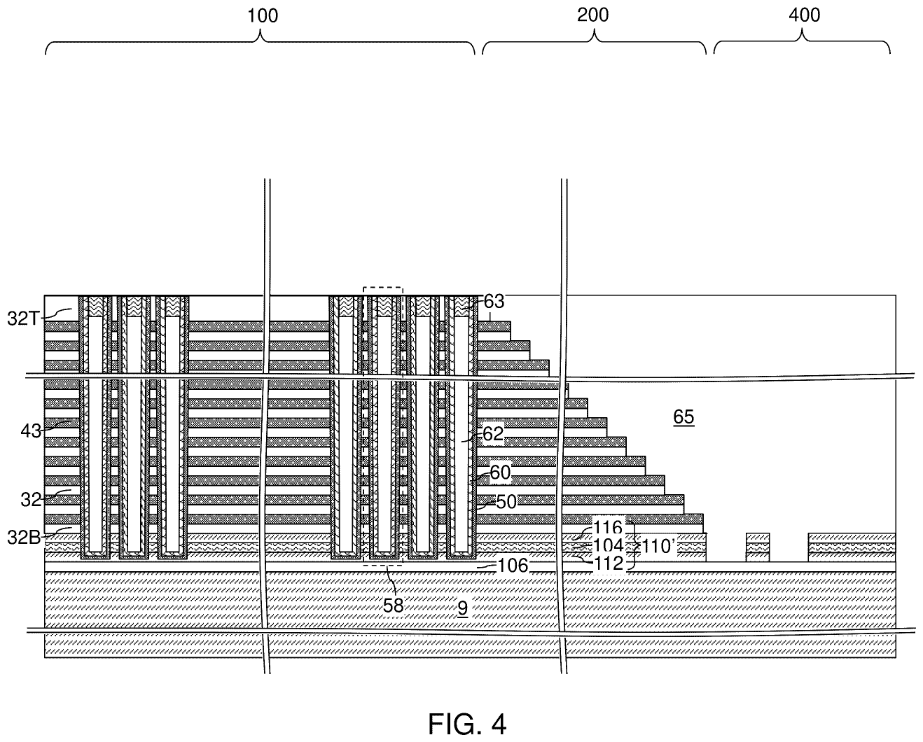

Referring to FIG. 4, the exemplary structure is illustrated after formation of memory opening fill structures 58 within the memory openings 49. Each of the memory opening fill structures 58 may comprise a memory stack structure 55, which comprises a memory film 50 and a vertical semiconductor channel 60. A combination of an alternating stack (32, 42) of insulating layers 32 and sacrificial material layers 42, memory openings 49 vertically extending through the alternating stack (32, 42), and memory opening fill structures 58 located in the memory openings 49 can be formed. Each of the memory opening fill structures 58 comprises a respective vertical stack of memory elements, such as portions of a memory material layer 54 located at levels of the sacrificial material layers 42.

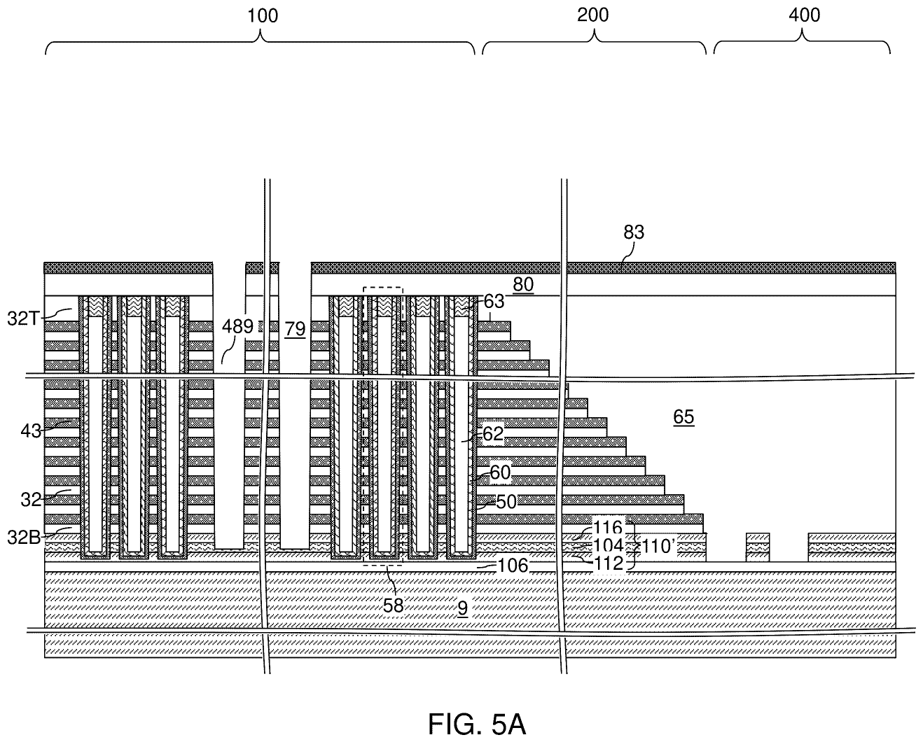

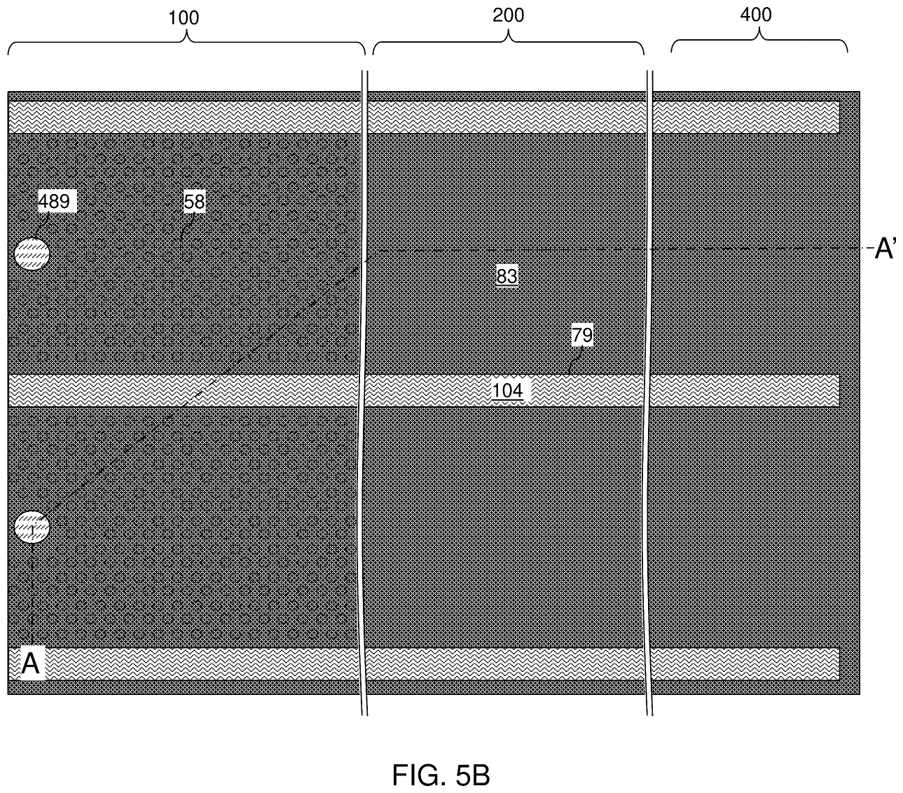

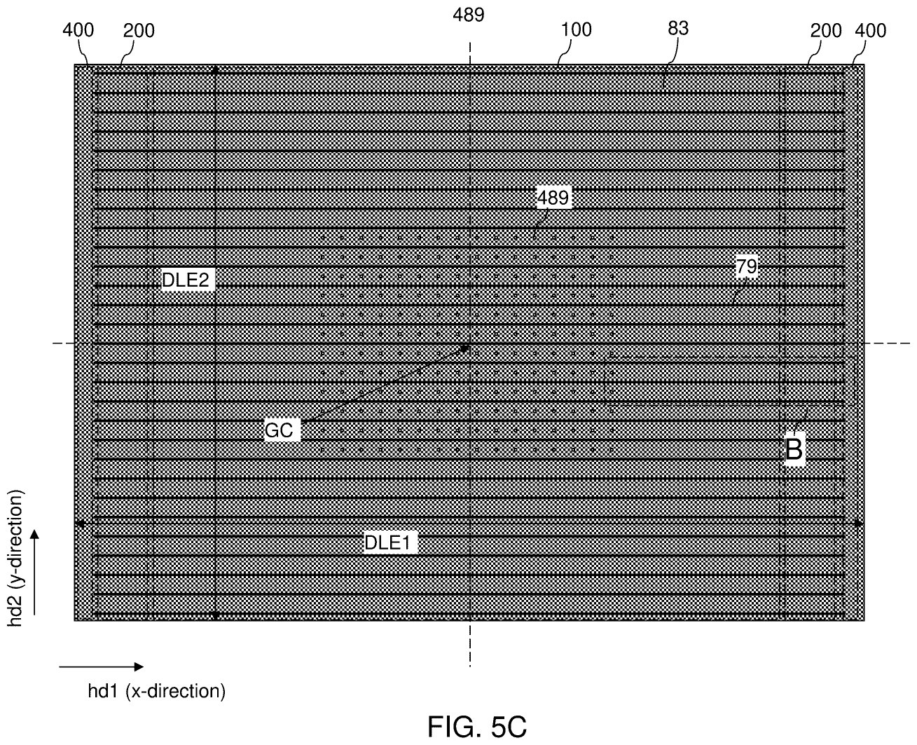

Referring to FIGS. 5A-5C, various views of the exemplary are illustrated after formation of a contact-level dielectric layer 80, a patterned hard mask layer 83, lateral isolation trenches 79, and through-stack openings 489. FIG. 5C is a top-down view of the exemplary structure that illustrates an entire area of an in-process memory die. FIG. 5B is a top-down view of region B of the top-down view of the exemplary structure shown in FIG. 5C. FIG. 5A is a vertical cross-sectional view of the exemplary structure along the vertical plane A-A′ of FIG. 5B.

Specifically, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A hard mask material can be deposited over the contact-level dielectric layer 80, and can be patterned to form a patterned hard mask layer 83. The hard mask layer 83 may comprise any suitable hard mask material, such as titanium nitride, polysilicon, silicon nitride, etc. The pattern of the openings in the patterned hard mask layer 83 may comprise elongated openings that laterally extend along the first horizontal direction hd1 between neighboring clusters (e.g., memory blocks) of memory opening fill structures 58 through the memory array region 100 and a pair of contact regions 200, and discrete openings having circular horizontal cross-sectional shapes.

An anisotropic etch process can be performed to transfer the pattern of the openings in the patterned hard mask layer 83 through the contact-level dielectric layer 80, the alternating stack (32, 42), the retro-stepped dielectric material portion 65, and upper layers of the in-process source-level material layers 110′. Lateral isolation trenches 79 laterally extending along the first horizontal direction hd1 can be formed through the alternating stack (32, 42), the retro-stepped dielectric material portion 65, the contact-level dielectric layer 80, and upper layers of the in-process source-level material layers 110′ underneath the elongated openings in the patterned hard mask layer 83. Through-stack openings 489 can be formed through the alternating stack (32, 42), the retro-stepped dielectric material portion 65, the contact-level dielectric layer 80, and upper layers of the in-process source-level material layers 110′ underneath the discrete openings in the patterned hard mask layer 83. In one embodiment, bottom surfaces of the lateral isolation trenches 79 and the through-stack openings 489 may comprise surface segments of the source-level sacrificial layer 104. In one embodiment, the through-stack openings 489 may be arranged as a two-dimensional periodic array.

In one embodiment, the through-stack openings 489 are formed in proximity to the geometrical center GC of the in-process memory die in a plan view. In one embodiment, peripheral regions of the in-process memory die may be free of any through-stack openings 489. A Cartesian coordinate system may be employed to represent locations within the in-process memory die. In this case, the origin can be located at the geometrical center GC of the in-process memory die, the x-value of the coordinates may have values in a range from −DLE1/2 to DLE1/2, and the y-value of the coordinates may have values in a range from −DLE2/2 to DLE2/2. In this case, the x-values of all coordinates representing the volumes of the through-stack openings 489 may be in a range from −a×DLE1/2 to a×DLE1/2, and the y-values of all coordinates representing the volumes of the through-stack openings 489 may be in a range from −b×DLE2/2 to b×DLE2/2. According to an aspect of the present disclosure, the value of a may be in a range from 0.1 to 0.9, and/or from 0.2 to 0.8, and/or from 0.3 to 0.7; and the value of b may be in a range from 0.1 to 0.9, and/or from 0.2 to 0.8, and/or from 0.3 to 0.7.

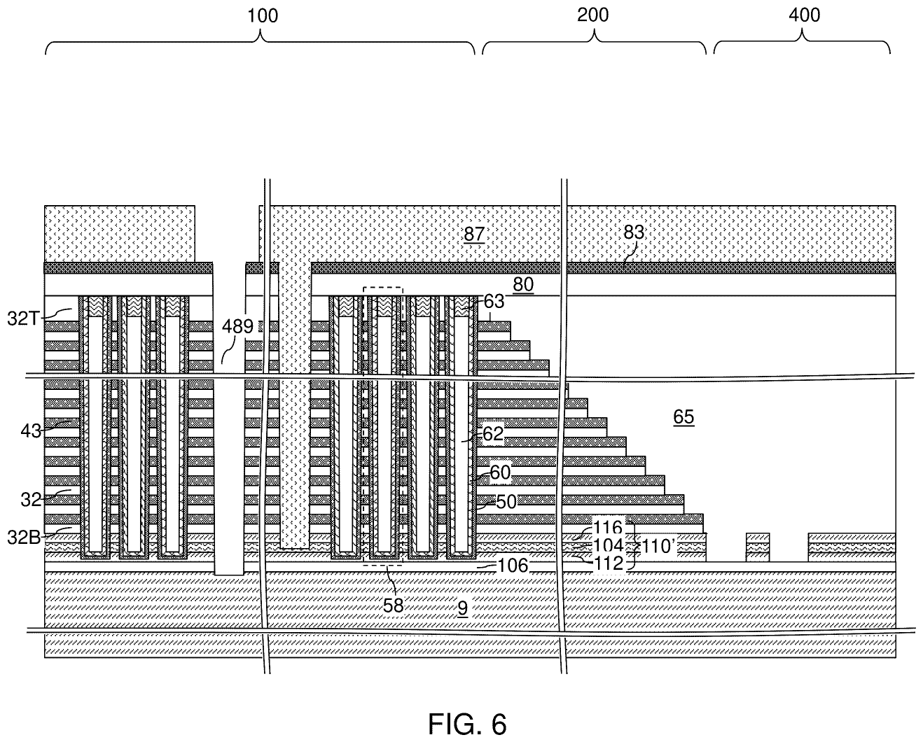

Referring to FIG. 6, a photoresist layer 87 can be applied over the exemplary structure, and can be lithographically patterned to form openings around the through-stack openings 489. The photoresist layer 87 can cover all areas of the lateral isolation trenches 79. An anisotropic etch process can be performed to vertically extend the through-stack openings 489 through the in-process source-level material layers 110′ and the backside dielectric layer 106 and optionally into an upper portion of the carrier substrate 9. The photoresist layer 87 can be subsequently removed, for example, by ashing. The patterned hard mask layer 83 can be removed selective to the contact-level dielectric layer, for example, by performing a wet etch process.

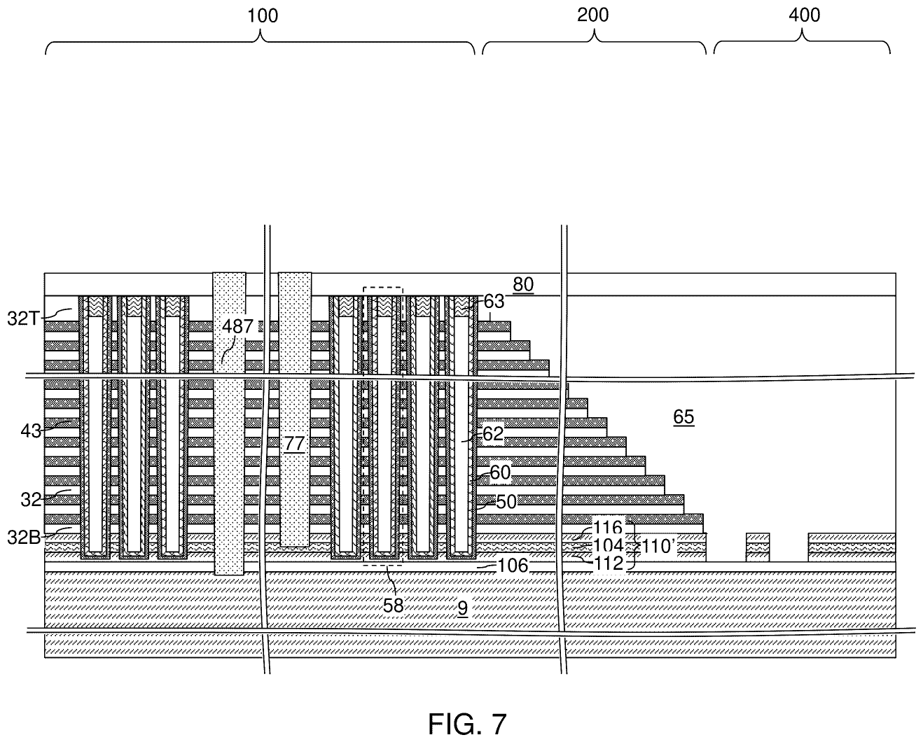

Referring to FIG. 7, a sacrificial fill material can be deposited in the lateral isolation trenches 79 and the through-stack openings 489. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the top surface of the contact-level dielectric layer 80. Remaining portions of the sacrificial fill material filling the lateral isolation trenches 79 constitute sacrificial lateral isolation trench fill structures 77. Remaining portions of the sacrificial fill material filling the through-stack openings 489 constitute sacrificial through-stack opening fill structures 487.

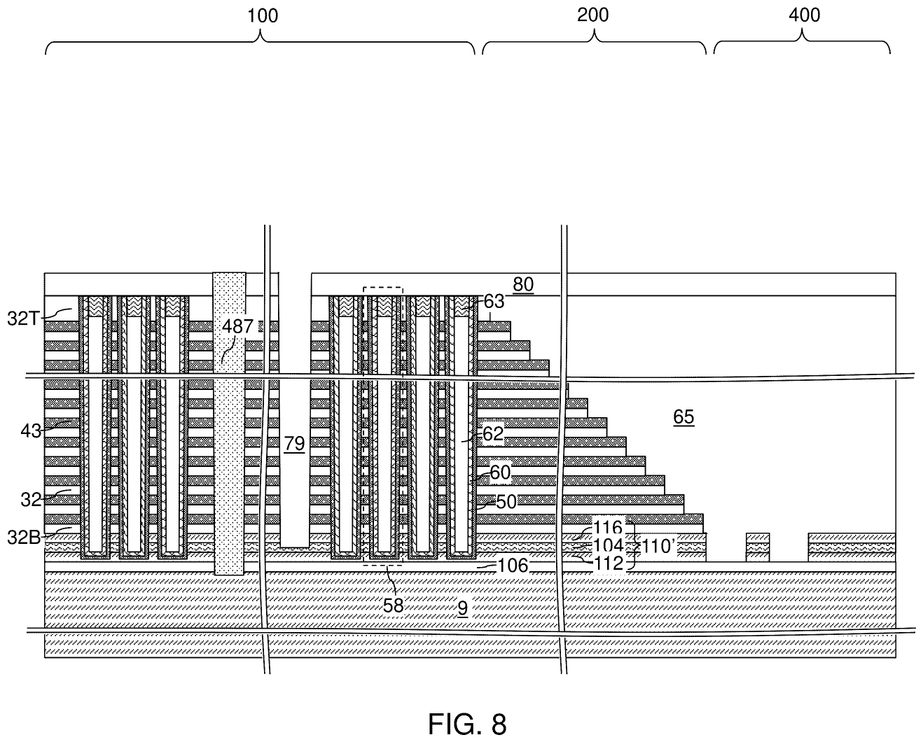

Referring to FIG. 8, a photoresist layer (not shown) can be applied over the contact-level dielectric layer 80, and can be lithographically patterned to cover the sacrificial through-stack opening fill structures 487 without covering the sacrificial lateral isolation trench fill structures 77. The sacrificial lateral isolation trench fill structures 77 can be removed selective to the materials of the contact-level dielectric layer 80 and the alternating stack (32, 42) to form cavities within the volumes of the lateral isolation trenches 79 (i.e., to reopen the lateral isolation trenches 79).

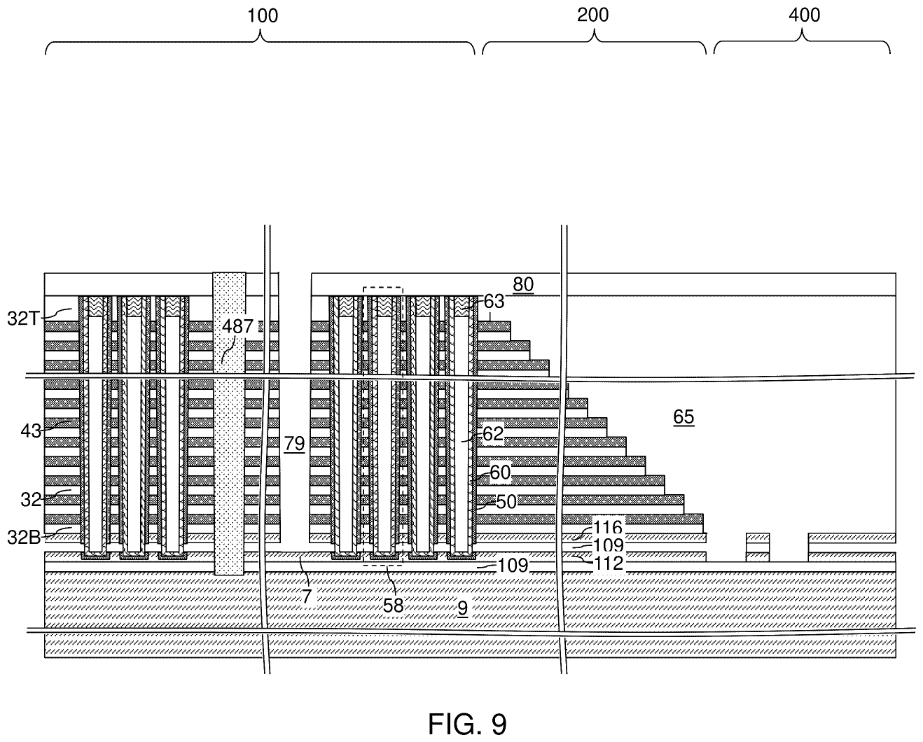

Referring to FIG. 9, an etch-stop spacer (not shown) may be optionally formed on sidewalls of the lateral isolation trenches by depositing and anisotropically etching an etch-stop barrier material, which may comprise silicon oxide or a dielectric metal oxide. An isotropic etch process can be performed to remove the source-level sacrificial layer 104 without removing the contact-level dielectric layer 80, the retro-stepped dielectric material portion 65, the lower source-level semiconductor layer 112, the upper source-level semiconductor layer 116, the upper sacrificial liner 105 (if present), and the lower sacrificial liner 103 (if present). For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact-level dielectric layer 80, the retro-stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

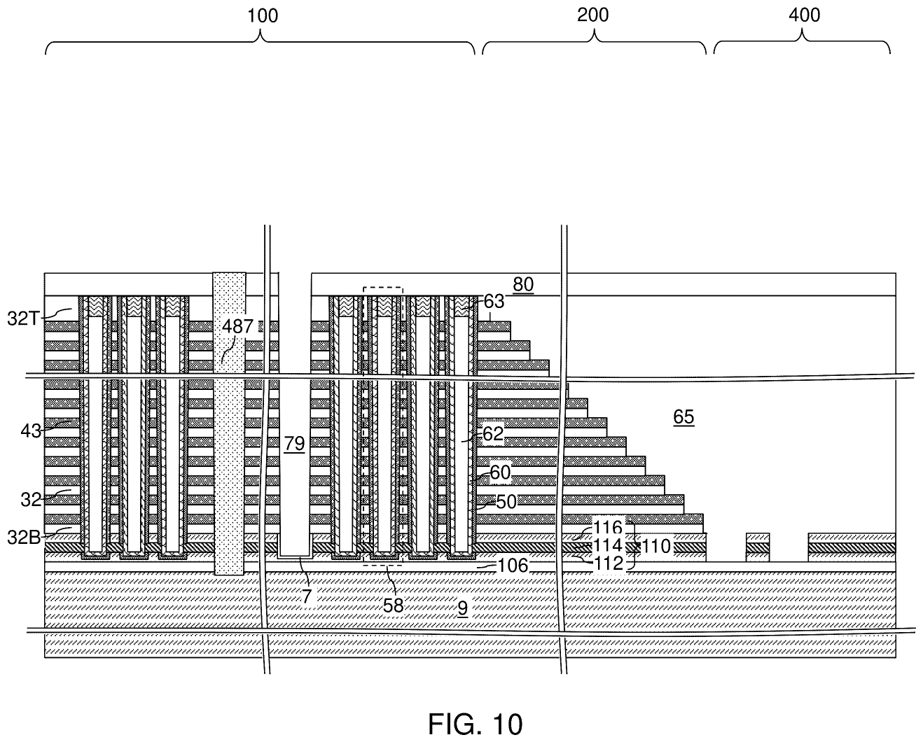

Referring to FIG. 10, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. Optionally, one or more etch back processes may be used in combination with a plurality of selective or non-selective deposition processes to provide a seamless and/or voidless source contact layer 114. Alternatively, the source contact layer 114 can be formed by performing a non-selective doped semiconductor material deposition process such as a low-pressure chemical vapor deposition process. In this case, an etch-back process can be performed to remove portions of the deposited doped semiconductor material that are deposited in the lateral isolation trenches 79 or above the contact-level dielectric layer 80. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³.

The layer stack including the lower source-level semiconductor layer 112, the source contact layer 114, and the upper source-level semiconductor layer 116 constitutes a source-level material layers 110, which replace the in-process source-level material layers 110′. The source-level material layers 110 contact a sidewall surface segment of each of the vertical semiconductor channels 60. An oxidation process can be performed to convert physically exposed portions of semiconductor material layer around bottom portions of the lateral isolation trenches 79. A semiconductor oxide liner 7, such as a silicon oxide liner, can be formed at the bottom of each lateral isolation trench 79.

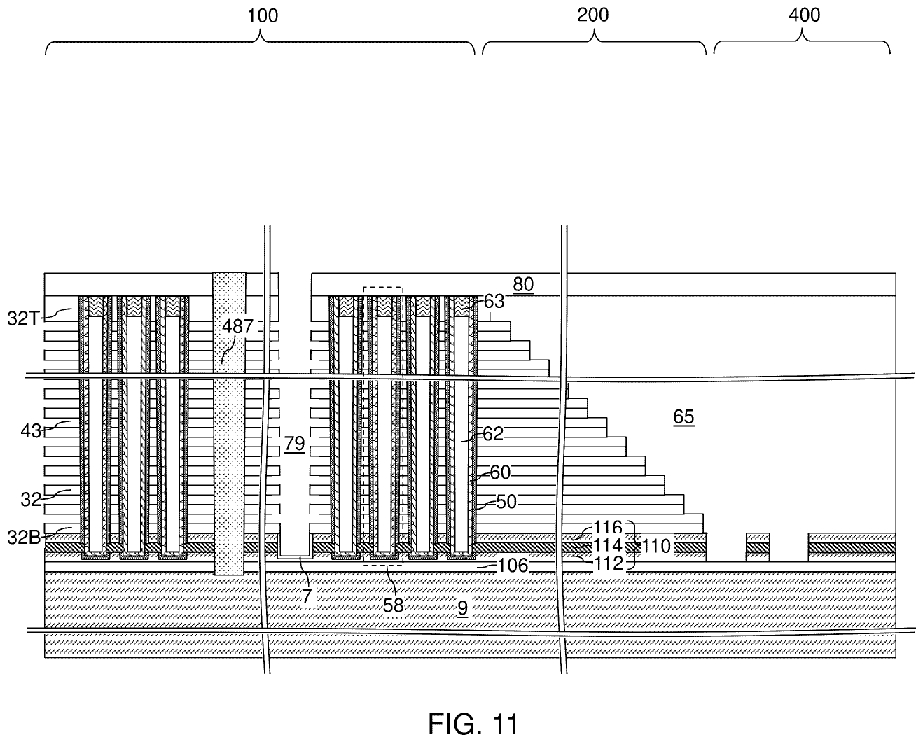

Referring to FIG. 11, an isotropic etch process can be performed to remove the sacrificial material layers 42 selective to the insulating layers 32, the semiconductor oxide liners 7, the memory opening fill structures 58, and the source-level material layers 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid, which is a process in which the exemplary structure is immersed in phosphoric acid at or near the boiling point of the phosphoric acid. A suitable clean process may be performed as needed. In summary, the laterally-extending cavities 43 can be formed by removing the sacrificial material layers 42 selective to the insulating layers 32 and the memory opening fill structures 58.

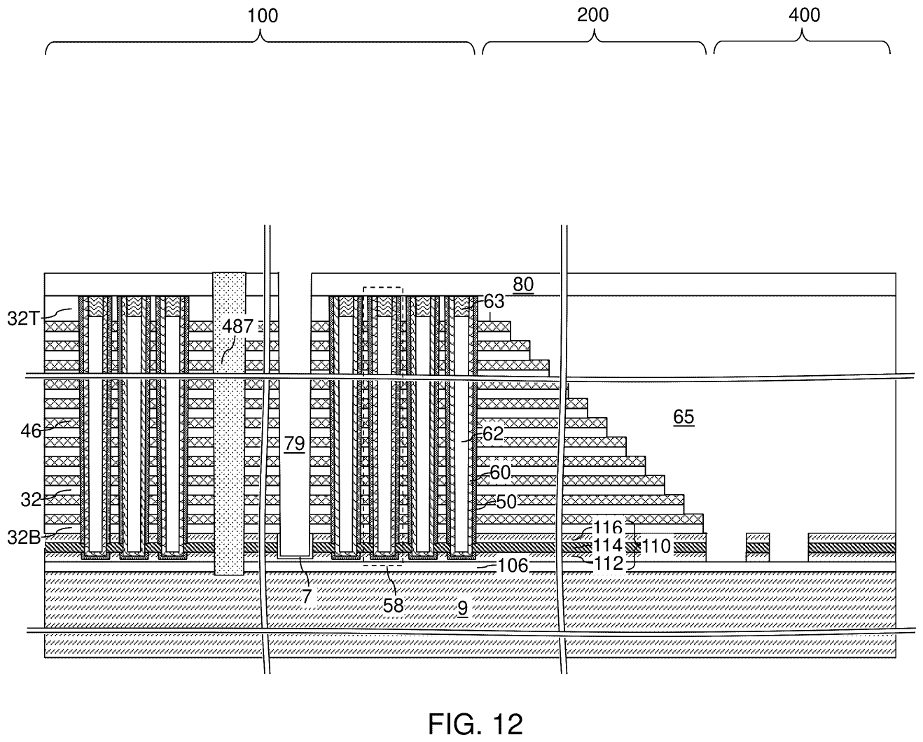

Referring to FIG. 12, a backside blocking dielectric layer (not shown) may be optionally is deposited in the laterally-extending cavities 43. The backside blocking dielectric layer, if employed, includes and/or consists essentially of a dielectric metal oxide material. At least one metallic material can be conformally deposited in the laterally-extending cavities 43. The at least one metallic material may comprise a combination of a metallic nitride barrier material and a metallic fill material. For example, the metallic nitride barrier material may comprise TiN, TaN, WN, or MoN, and the metallic fill material may comprise W, Ru, Mo, Co, etc.

An anisotropic etch process can be performed to remove portions of the at least one metallic material and optionally the backside blocking dielectric layer from inside the volumes of the lateral isolation trenches 79 and from above the contact-level dielectric layer 80. Each contiguous remaining portion of the at least one metallic material located within a volume of a respective laterally-extending cavity 43 constitutes an electrically conductive layer 46. Alternating stacks (32, 46) of insulating layers 32 and electrically conductive layers 46 is formed between each neighboring pair of lateral isolation trenches 79. Thus, the alternating stacks (32, 46) of insulating layers 32 and electrically conductive layers 46 can be laterally spaced apart from each other along the second horizontal direction hd2 by the lateral isolation trenches 79.

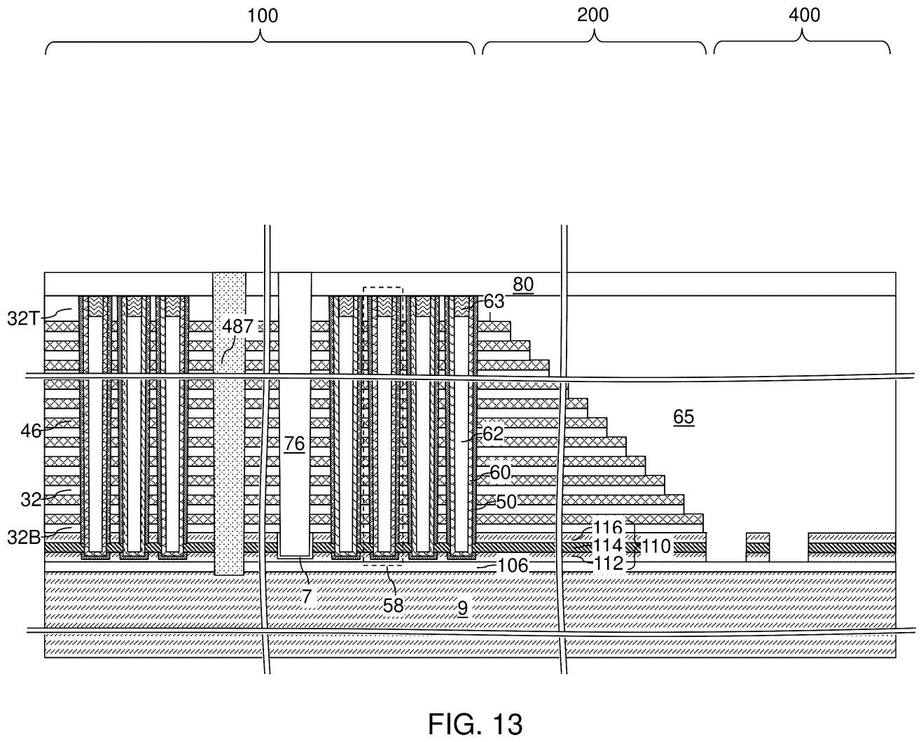

Referring to FIG. 13, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes a lateral isolation trench fill structure 76. Alternatively, each lateral isolation trench fill structure 76 may comprise a combination of a tubular insulating spacer (not expressly shown) and a conductive connection via structure (not expressly shown) that is laterally surrounded by the tubular insulating spacer. In summary, a lateral isolation trench fill structure 76 having insulating sidewalls can be formed within each lateral isolation trench 79. Each lateral isolation trench fill structure 76 vertically extends from a bottommost surface of an alternating stack (32, 46) to a topmost surface of the alternating stack (32, 46).

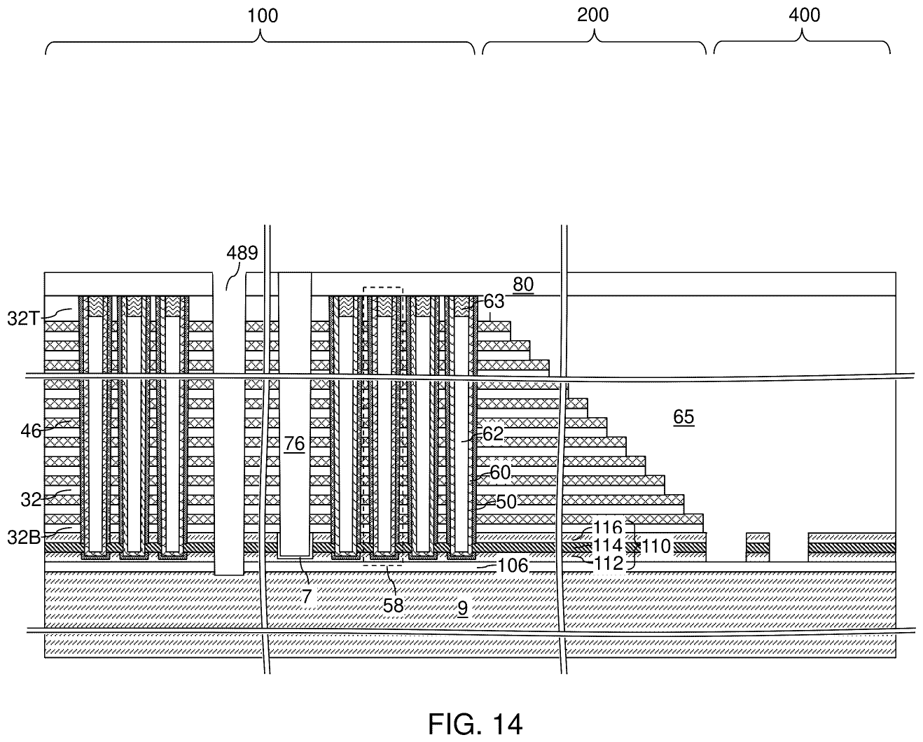

Referring to FIG. 14, a selective etch process can be performed to remove the sacrificial through-stack opening fill structures 487 selective to the materials of the contact-level dielectric layer 80 and the alternating stacks (32, 42). Cavities are formed in the volumes of the through-stack openings 489.

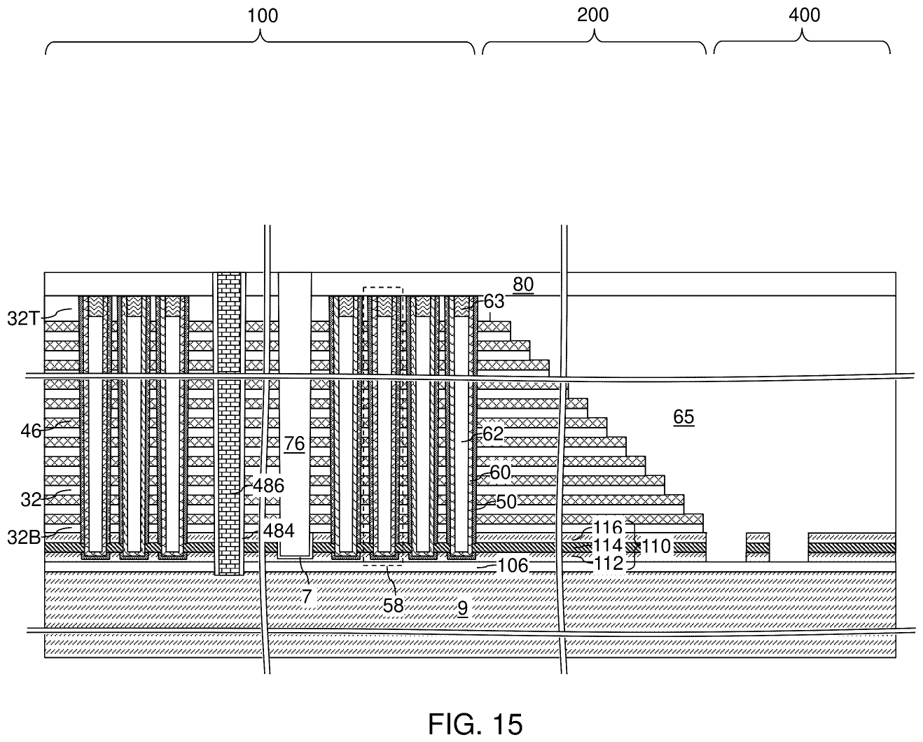

Referring to FIG. 15, a dielectric material, such as silicon oxide, can be conformally deposited in peripheral portions of the through-stack openings 489. An anisotropic etch process can be performed to remove horizontally-extending portions of the deposited dielectric material. Each remaining tubular portion of the deposited dielectric material located in peripheral regions of the through-stack openings 489 constitutes a tubular dielectric spacer 484. The lateral thickness of each tubular dielectric spacer 484 (as measured between an inner sidewall and an outer sidewall) may be in a range from 30 nm to 100 nm, although lesser and greater thicknesses may also be employed.

At least one conductive material, such as at least one metallic material, can be deposited in center regions of the through-stack openings 489. Excess portions of the at least one conductive material can be removed from above the horizontal plane including the top surface of the contact-level dielectric layer 80 by performing a planarization process such as a chemical mechanical planarization process. Each remaining portion of the at least one conductive material that remains in a respective through-stack opening 489 comprises a through-stack via structure 486.

The through-stack via structures 486 are formed in a center region of the in-process memory die. As used herein, the center region is defined as a volume within the in-process memory die that is more proximal to the geometrical center GC of the in-process memory die than to a periphery of the in-process memory die. The periphery is defined by the outer boundary of the in-process memory die in a plan view along a vertical direction.

In one embodiment, at least one of the vertically-extending openings 489 in the alternating stacks (32, 46) is entirely laterally surrounded by a respective one of the alternating stacks (32, 46). In one embodiment, the entirety of at least one of the vertically-extending openings 489 may be located within the area of a respective one of the alternating stacks (32, 46) in the plan view. In one embodiment, at least one of the through-stack via structures 486 is located within a respective one of the vertically-extending openings 489, and is laterally spaced from a sidewall of the respective one of the vertically-extending opening 489 by a respective tubular dielectric spacer 484.

In one embodiment, sidewalls of the through-stack openings 489 may be tapered such that each through-stack opening 489 has a greater lateral dimension at its top than at its bottom. In one embodiment, sidewalls of the through-stack via structures 486 are tapered relative to a vertical direction such that each of the through-stack via structures 486 has a respective variable horizontal cross-sectional area that increases with a vertical distance from the carrier substrate 9.

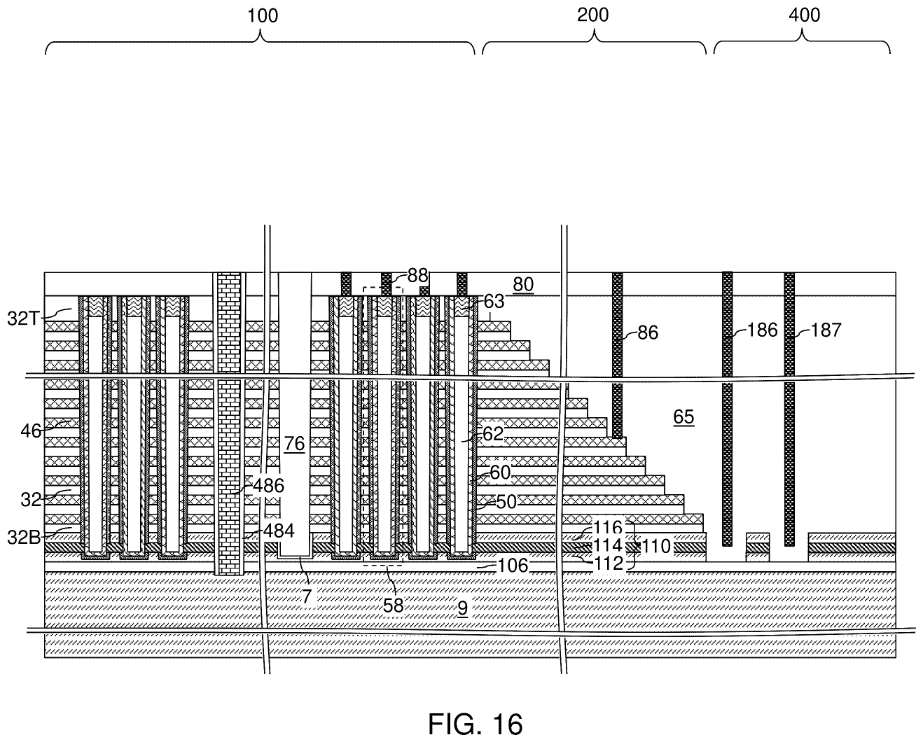

Referring to FIG. 16, a photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via cavities can be formed through the contact-level dielectric layer 80 and the retro-stepped dielectric material portion 65 on a top surface of a respective one of the electrically conductive layers 46. Peripheral edge seal cavities and peripheral connection via cavities can be formed in the peripheral region 400. The photoresist layer can be subsequently removed, for example, by ashing.

At least one conductive material, such as a combination of a metallic barrier material and a metal fill material, can be deposited in the drain contact via cavities, the layer contact via cavities, and peripheral connection via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46. Remaining portions of the at least one conductive material that fill the respective peripheral connection via cavities and the peripheral connection via cavities constitute peripheral connection via cavities 186 and peripheral edge seal structures 187.

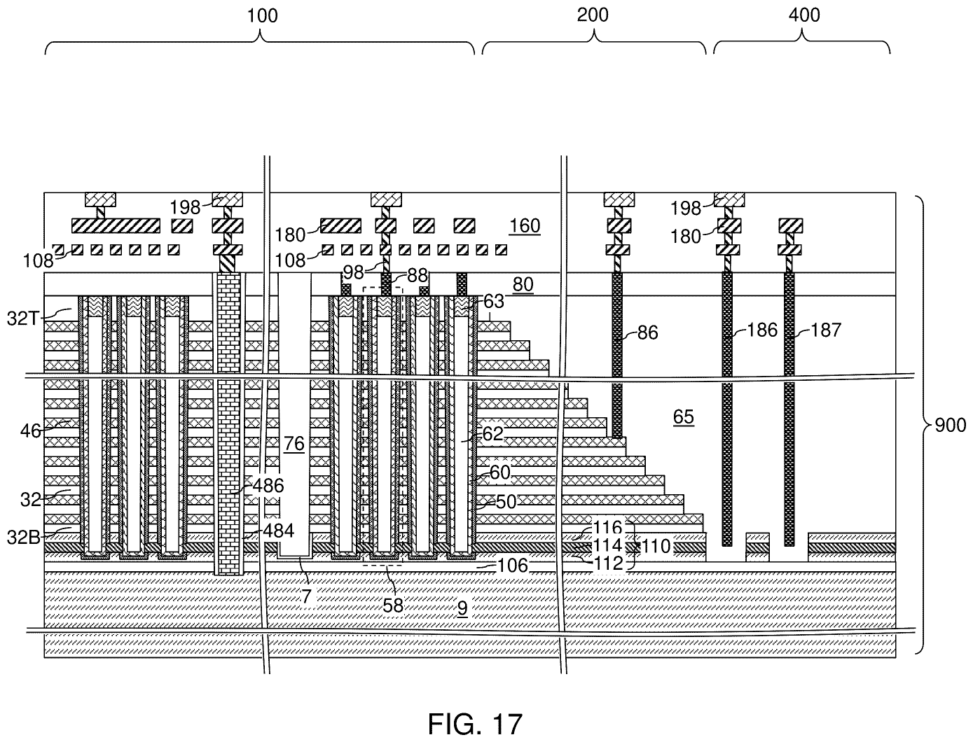

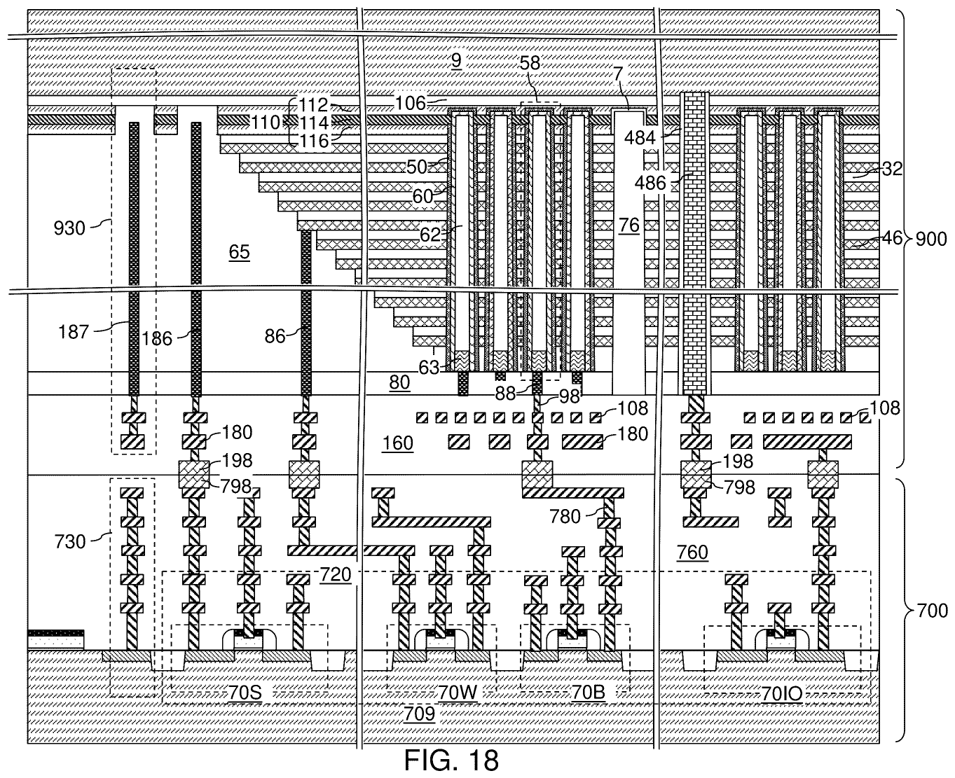

Referring to FIG. 17, additional dielectric material layers embedding metal interconnect structures can be formed over the contact-level dielectric layer 80. The additional dielectric material layers are herein referred to as memory-side dielectric material layers 160. The metal interconnect structures are herein referred to as memory-side metal interconnect structures (98, 108, 180). The memory-side metal interconnect structures (98, 108, 180) may include bit lines 108 that laterally extend along the second horizontal direction hd2, bit-line-connection via structures 98 that connect the drain contact via structures 88 with the bit lines 108, and additional metal interconnect structures 180 which include various types of metal via structures and various types of metal lines.

Memory-side bonding pads 198 configured for metal-to-metal bonding can be formed in the topmost dielectric layer of the memory-side dielectric material layers 160. Metal-to-metal bonding involves direct attachment of contacting metal surfaces to each other without use of any intermediate material. An exemplary metal-to-metal bonding process comprises a copper-to-copper bonding in which mating copper surfaces are pushed against each other at an elevated temperature, which may be in a range from 200 degrees Celsius to 400 degrees Celsius. In one embodiment, the memory-side bonding pads 198 may have physically exposed copper surfaces.

The exemplary structure comprises a memory die 900. In one embodiment, a two-dimensional array of memory dies 900 may be formed on the same carrier substrate 9. For example, the carrier substrate 9 may comprise a commercially available silicon wafer, and the two-dimensional array of memory dies 900 may comprise a periodic rectangular array of memory dies 900 comprising a respective portion of the silicon wafer.

Referring to FIG. 18, a logic die 700 is provided. The logic die 700 comprises a peripheral circuit 720 that is formed on a logic-side substrate 709. According to an aspect of the present disclosure, the peripheral circuit 720 can be configured to control operation of the memory array within the memory die 900. For example, the peripheral circuit 720 may comprise word line drivers 70W configured to drive word lines, which are a subset of the electrically conductive layers 46 within the alternating stacks (32, 46). The peripheral circuit 720 may comprise bit line drivers 70B configured to drive the bit lines 108 in the memory die 900. The bit lines 108 are electrically connected to first ends (i.e., the ends that are connected to the drain regions 63) of a respective subset of the memory stack structures 55. The peripheral circuit 720 may comprise source line drivers 70S configured to drive source layers to be subsequently formed on the memory die 900 after removal of the carrier substrate 9. The peripheral circuit 720 may also comprise input/output control devices 7010 configured to receive input data from or configured to transmit output data to at least one conductive pad to be subsequently formed on the through-stack via structures 486 after removal of the carrier substrate 9.

Logic-side metal interconnect structures 780 embedded within logic-side dielectric material layers 760 can be provided over the peripheral circuit 720. The logic die 700 comprises logic-side bonding pads 798 embedded within logic-side dielectric material layers 760. The logic-side bonding pads 798 can be electrically connected to a respective electrical node of the peripheral circuit 720, and can be arranged in a pattern that is a mirror image pattern of the memory-side bonding pads 198 of the memory die 900.

A bonded assembly can be formed by bonding the logic die 700 with the memory die 900. The logic die 700 can be attached to the memory die 900, for example, by bonding the logic-side bonding pads 798 to the memory-side bonding pads 198. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 798 within each logic die 700 can be bonded to the memory-side bonding pads 198 within a respective memory die 900. The logic-side bonding pads 798 within each logic die 700 can be bonded to the memory-side bonding pads 198 within a respective memory die 900 by metal-to-metal bonding, such as copper-to-copper bonding.

The memory die 900 comprises alternating stacks (32, 46) of insulating layers 32 and electrically conductive layers 46 and memory-side dielectric material layers 160 embedding memory-side metal interconnect structures (180, 108, 98) and memory-side bonding pads 198. Memory stack structures 55 vertically extend through a respective one of the alternating stacks (32, 46) in a memory array region 100, and layer contact via structures 86 contact a respective electrically conductive layer 46 within the alternating stacks (32, 46) in a contact region 200. Through-stack via structures 486 vertically extend through vertically-extending openings 489 in the alternating stacks (32, 46) within a center region of the memory die 900, which is defined as a volume within the memory die 900 that is more proximal to a geometrical center GC of the memory die 900 than to a periphery of the memory die 900 defined by outer sidewalls of the memory die 900 in a plan view along a vertical direction. A logic die 700 comprises a peripheral circuit 720 including a control circuitry for controlling operation of the electrically conductive layers 46 and further comprises logic-side dielectric material layers 760 embedding logic-die metal interconnect structures 780 and logic-side bonding pads 798. The logic-side bonding pads 798 are bonded to the memory-side bonding pads 198.

A subset of the through-stack via structures 486 is electrically connected to a subset of semiconductor devices (e.g., input/output control devices 7010, such as field effect transistors) in the logic die 700 through a subset of the memory-side metal interconnect structures (180, 108, 98) and through a subset of the logic-die metal interconnect structures 780. The peripheral edge seal structures 187 comprise components of a memory-side edge seal structure 930, and a subset of the logic-side metal interconnect structures 780 may be employed as components of a logic-side edge seal structure 730.

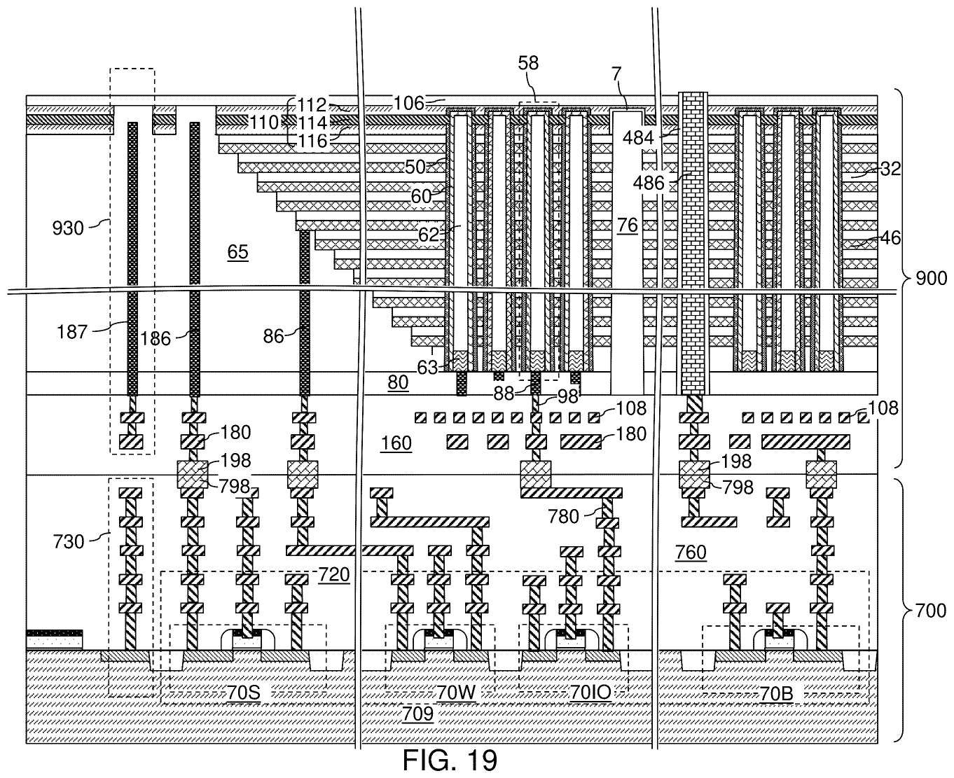

Referring to FIG. 19, the carrier substrate 9 may be removed, for example, by grinding, polishing, cleaving, an isotropic etch process, and/or an anisotropic etch process. If a polishing process such as a chemical mechanical polishing process is employed to remove the carrier substrate 9, the backside dielectric layer 106 may be subsequently employed as a polishing stopper material layer. If an etch process such as a wet etch process is employed to remove the carrier substrate 9, the backside dielectric layer 106 may be subsequently employed as an etch stop material layer. End surfaces of the through-stack via structures 486 may be physically exposed upon removal of the carrier substrate 9.

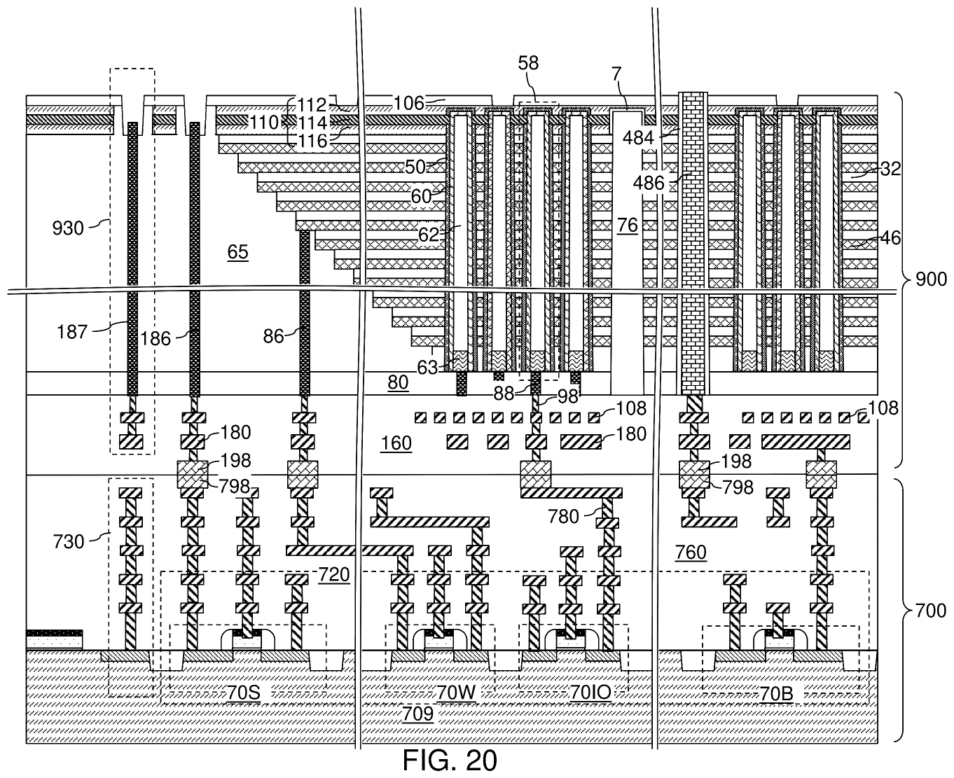

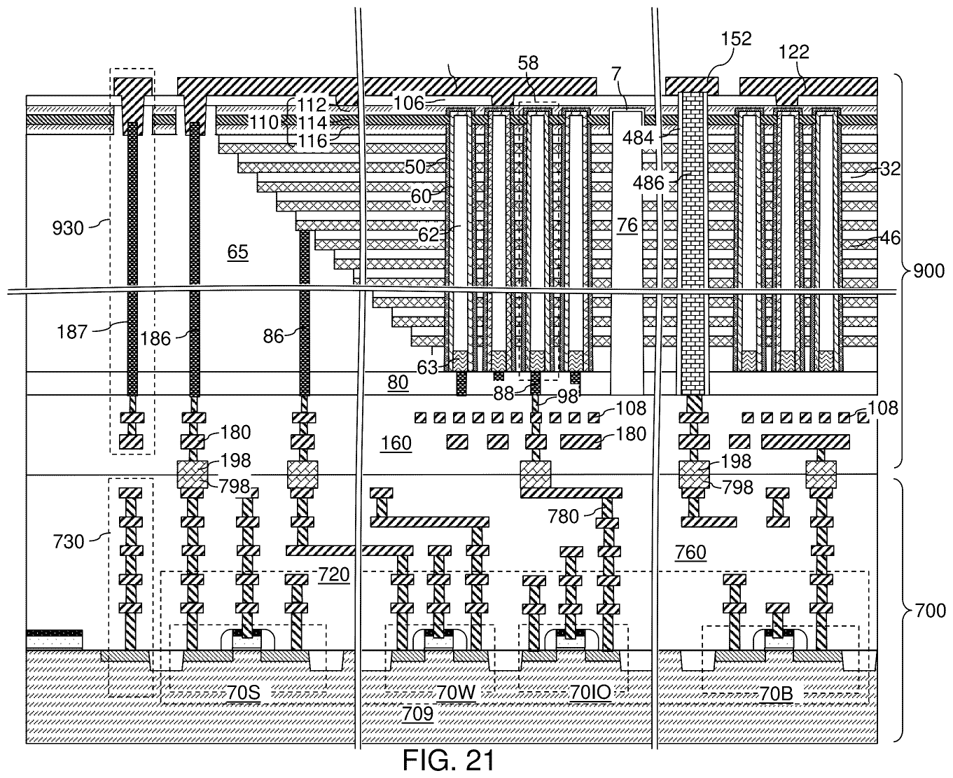

Referring to FIG. 20, openings can be formed through the backside dielectric layer 106 on the backside surface (i.e., a distal surface) of the source-level material layers 110 by performing a combination of a lithographic patterning process and an anisotropic etch process. Additional openings can be formed through the backside dielectric layer 106 and through the source-level material layers 110 over the end portions of the peripheral connection via structures 186 and the peripheral edge seal structures 187 by performing a combination of an additional lithographic patterning process and an additional anisotropic etch process.

Referring to FIG. 21, at least one electrically conductive material can be deposited in the openings, over the distal surface of the backside dielectric layer 106, and over end portions of the memory stack structures 55 that are distal from an interface between the memory die 900 and the logic die 700 to form a backside conductive layer. The backside conductive layer can be subsequently patterned to form at least one conductive source layer 122 and backside conductive pads 152. Each of the at least one conductive source layer 122 may be electrically connected to a respective source line driver 70S through a respective peripheral connection via structure 186, a respective subset of the memory-side metal interconnect structures 180, a respected bonded pair of a logic-side bonding pad 798 and a memory-side bonding pad 198, and a respective subset of the logic-side metal interconnect structures 780. Each conductive source layer 122 is electrically connected to the end portions of a respective subset of the memory stack structures 55 (e.g., to end portions of the vertical semiconductor channels 60). Each of the through-stack via structures 486 may be physically and/or electrically connected to a respective one of the backside conductive pads 152. At least a subset of the backside conductive pads 152 can be electrically connected to a respective input/output control device 7010 through a respective through-stack via structure 486, a respective subset of the memory-side metal interconnect structures 180, a respected bonded pair of a logic-side bonding pad 798 and a memory-side bonding pad 198, and a respective subset of the logic-side metal interconnect structures 780.

In one embodiment, each of the at least one conductive source layer 122 and the backside conductive pads 152 may comprise a conductive layer stack that is compatible with a solder bonding process. For example, each of the at least one conductive source layer 122 and the backside conductive pads 152 may comprise, from bottom to top, a metallic barrier liner comprising a conductive metallic nitride material (such as TiN, TaN, WN, or MoN), a high-electrical-conductively metal layer comprising copper or aluminum, a metallic diffusion barrier liner comprising a diffusion barrier metallic material, such as Ti, TiW, Ta, or TaN, an adhesion layer enhancing the adhesion strength of subsequently deposited layers and comprising a material such as Cr, Ti, or a Cr/Ti alloy, and an under-bump metallization (UBM) layer. The UBM layer may comprise a multi-layer stack, such as a layer stack of a copper layer, a nickel layer, and a gold layer. Alternative UBM layer compositions may also be employed.

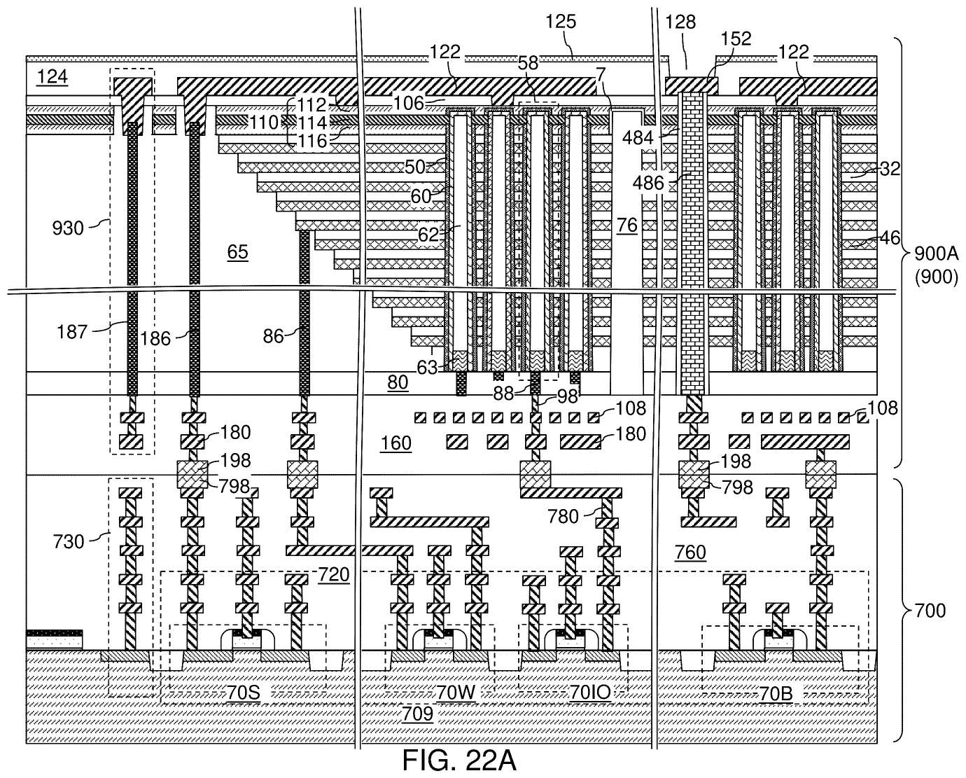

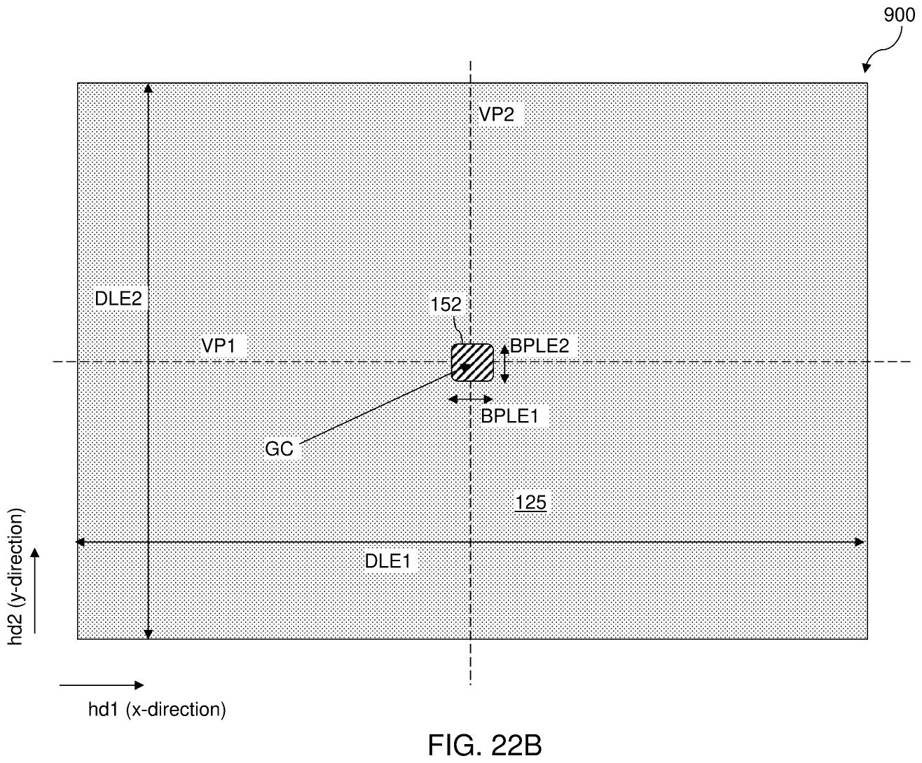

Referring to FIGS. 22A and 22B, a backside passivation layer (124, 125) can be formed over the at least one conductive source layer 122 and the backside conductive pads 152. The backside passivation layer (124, 125) may comprise a stack of a silicon oxide passivation layer 124 and a silicon nitride passivation layer 125. A photoresist layer can be applied over the backside passivation layer (124, 125), and can be lithographically patterned to form openings over the backside conductive pads 152. An anisotropic etch process can be performed to form openings 128 through the backside passivation layer (124, 125) over each of the backside conductive pads 152.

In one embodiment, the backside conductive pads 152 may be external bonding pads, which can be solder bonding pads that are employed to bond solder balls. C4 bonding or wirebonding can be performed to electrically connect the backside conductive pads 152 to external electrical nodes. Functionally, the backside conductive pads 152 may be input/output pads that are electrically connected to the input/output control devices 7010 in the logic die 700. The memory die 900 illustrated in FIGS. 22A and 22B comprises backside conductive pads 152 that are configured for performing solder bonding on the backside conductive pads 152, and is herein referred to as a first-type memory die 900A.

In one embodiment shown in FIG. 22B, the backside conductive pads 152 are formed in proximity to the geometrical center GC of the memory die 900 in a plan view. In one embodiment, peripheral regions of the backside conductive pads 152 may be free of any backside conductive pads 152. The memory die 900 may have a rectangular shape in a plan view, such as a top-down view. In one embodiment, the memory die 900 may have a first lateral dimension DLE1 (i.e., a first lateral extent) along a first horizontal direction hd1, which is also referred to as an x-direction of a Cartesian coordinate system representing locations within the memory die. The memory die 900 may have a second lateral dimension DLE2 (i.e., a second lateral extent) along a second horizontal direction hd2, which is also referred to as a y-direction of the Cartesian coordinate system. A first vertical plane VP1 that bisects the memory die 900 and is parallel to the first horizontal direction hd1, and a second vertical plane VP2 that bisects the memory die 900 and is parallel to the second horizontal direction hd2 intersect at the geometrical center GC of the memory die 900.

A Cartesian coordinate system may be employed to represent locations within the memory die 900. In this case, the origin can be located at the geometrical center GC of the memory die 900. The x-value of the coordinates may have values in a range from −DLE1/2 to DLE1/2, and the y-value of the coordinates may have values in a range from −DLE2/2 to DLE2/2. In this case, the x-values of all coordinates representing any point within the at least one backside conductive pad 152 may be in a range from −a×DLE1/2 to a×DLE1/2, and the y-values of all coordinates representing any point within the at least one backside conductive pad 152 may be in a range from −b×DLE2/2 to b×DLE2/2. In one embodiment, the value of a may be in a range from 0.1 to 0.9, and/or from 0.2 to 0.8, and/or from 0.3 to 0.7; and the value of b may be in a range from 0.1 to 0.9, and/or from 0.2 to 0.8, and/or from 0.3 to 0.7. In this case, the first backside pad lateral extent BPLE1 equals the product of a and the first lateral dimension DLE1, and the second backside pad lateral extent BPLE2 equals the product of b and the second lateral dimension DLE2. While one backside conductive pad 152 is shown in FIGS. 22A and 22B, in an alternative embodiment, a plurality of backside conductive pads 152 may be formed over the memory die 900A.

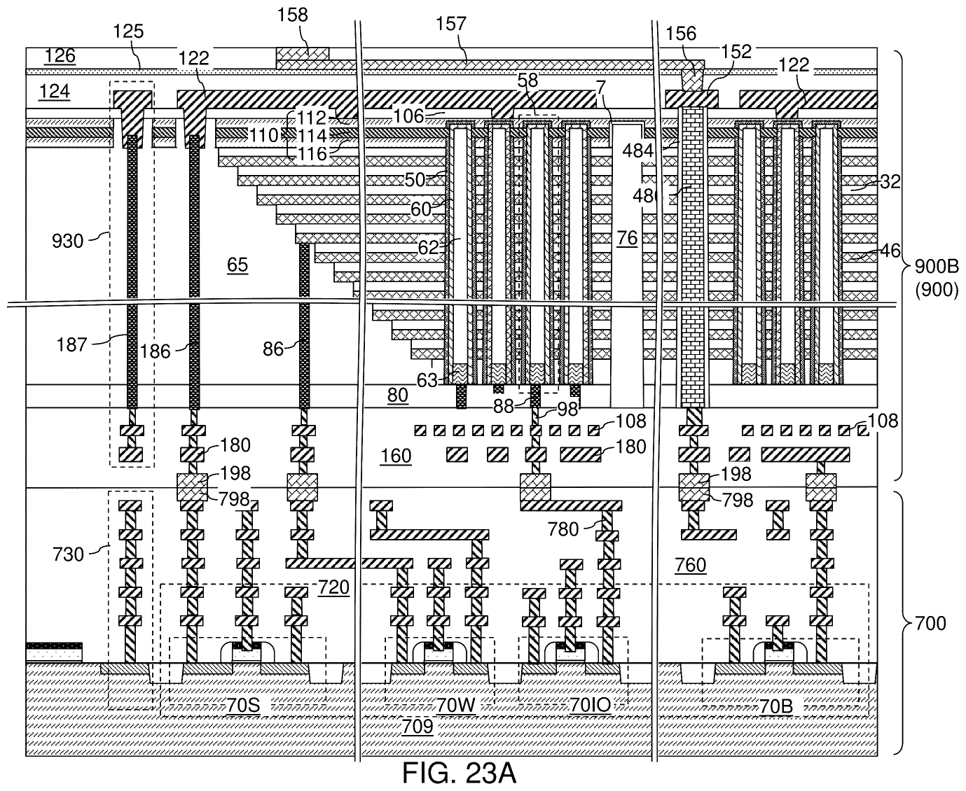

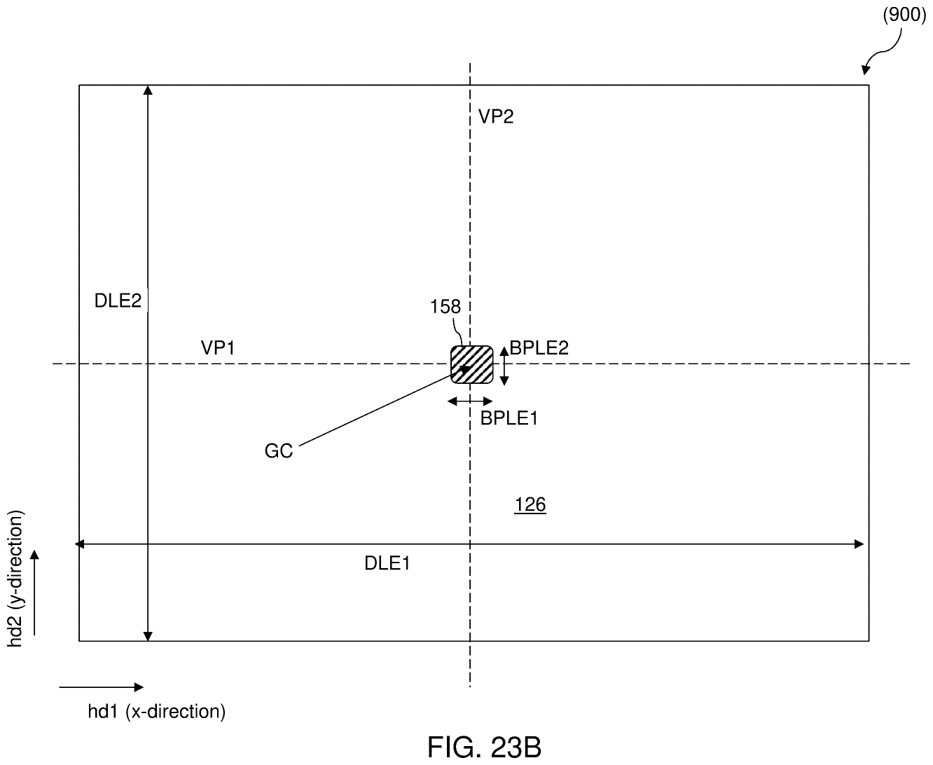

Referring to FIGS. 23A and 23B, an alternative configuration of the exemplary structure can be derived from the exemplary structure illustrated in FIG. 21 by forming the backside conductive layer employing at least one conductive material that is suitable for an embedded metal interconnect structure. For example, the backside conductive layer may comprise and/or may consist of a layer stack including a metallic barrier liner comprising a conductive metallic nitride material (such as TiN, TaN, WN, or MoN), and a high-electrical-conductively metal layer comprising copper or aluminum. Thus, under-bump metallurgy layers are not employed for the backside conductive layer. Accordingly, each of the at least one conductive source layer 122 and the backside conductive pads 152 does not include under-bump metallurgy layers.

Subsequently, the backside passivation layer (124, 125) is deposited and via cavities can be formed through the backside passivation layer (124, 125) to expose the backside conductive pads 152. The via cavities are filled with at least one conductive material, such as a metallic barrier material (such as TiN, TaN, WN, or MoN) and a high conductivity metal, such as aluminum or copper, to form conductive vias 156. A conductive line 157 is then formed over the backside passivation layer (124, 125) and in contact with the conductive vias 156. The conductive line 157 may comprise a metallic barrier material (such as TiN, TaN, WN, or MoN) and a high conductivity metal, such as aluminum or copper.

A bonding-level dielectric layer 126 can be formed over the conductive line 157. The bonding-level dielectric layer 126 may comprise a dielectric material that may be employed for dielectric-to-dielectric bonding. For example, the bonding-level dielectric layer 126 may comprise silicon oxide. A pad cavity which exposes a portion of the conductive line 157 is formed in the bonding-level dielectric layer 126 and filled with at least one electrically conductive material. For example, a combination of a metallic barrier material (such as TiN, TaN, WN, or MoN) and copper can be deposited in the pad cavities. Excess portions of the at least one conductive material can be removed from above the horizontal plane including the top surface of the bonding-level dielectric layer 126, for example, by a chemical mechanical polishing process. Remaining portions of the at least one conductive material that fills the pad cavities constitute backside bonding pads 158. In this case, the memory die 900 comprises a bonding-level dielectric layer 126 overlying the conductive source layer 122 and the backside conductive pads 152, and backside bonding pads 158 embedded in the bonding-level dielectric layer 126 and electrically connected to a respective one of the backside conductive pads 152 through the conductive line 157 and the conductive via 156. The backside bonding pads 158 are configured for metal-to-metal bonding and have physically exposed copper surfaces.

The memory die 900 illustrated in FIGS. 23A and 23B includes backside bonding pads 158 configured for performing metal-to-metal bonding with another semiconductor die (such as another memory die), and is herein referred to as a second-type memory die 900B. In the second-type memory die 900B, the backside conductive pads 152 are not employed as bonding pads. The backside bonding pads 158 are configured for metal-for-metal bonding, and a predominant fraction (i.e., more than 50%) of all physically exposed surfaces of the backside bonding pads 158 may be copper surfaces.

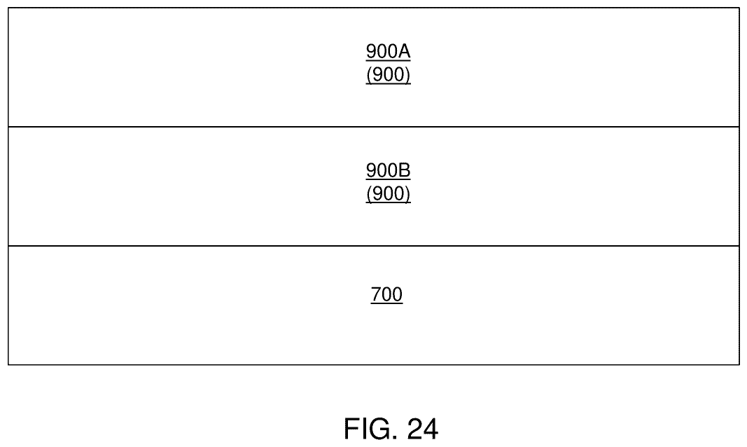

Referring to FIG. 24, an assembly of a logic die 700 and two memory dies 900 is illustrated, which can be derived from the alternative configuration of the exemplary structure illustrated in FIGS. 23A and 23B by bonding another memory die 900, which can be configured as the first-type memory die 900A and includes memory-side bonding pads 198 that are configured for metal-to-metal bonding and arranged in a mirror pattern of the pattern of the backside bonding pads 158 in the second-type memory die 900B illustrated in FIGS. 23A and 23B. In this case, two memory dies 900 can be bonded to a logic die 700, and the backside conductive pads 152 located in the distal memory die 900, i.e., the first-type memory die 900A, that is not directed attached to the logic die 700, may be employed as external bonding pads to which solder balls are attached for C4 bonding or wirebonding.

Referring collectively to FIGS. 1-24 and according to various embodiments of the present disclosure, a bonded assembly of a memory die 900 and a logic die 700 is provided. The memory die 900 comprises alternating stacks (32, 46) of insulating layers 32 and electrically conductive layers 46; memory-side dielectric material layers 160 embedding memory-side metal interconnect structures (180, 108, 98) and memory-side bonding pads 198; memory stack structures 55 each comprising a memory film 50 and a vertical semiconductor channel 60 vertically extending through the alternating stack in a memory array region 100; layer contact via structures 86 contacting a respective electrically conductive layer 46 within the alternating stack (32, 46) in a contact region 200; and a through-stack via structure 486 vertically extend through a vertically-extending opening 489 in the alternating stack (32, 46) within a center region of the memory die 900 which comprises a volume within the memory die 900 that is more proximal to a geometrical center GC of the memory die 900 than to a periphery of the memory die 900 defined by outer sidewalls of the memory die 900 in a plan view along a vertical direction; and a backside conductive pad 152 electrically contacting the through-stack via structure 486. The logic die 700 comprises a peripheral circuit 720 and logic-side bonding pads 798 which are bonded to the memory-side bonding pads 198.

In one embodiment, the logic die 700 further comprises logic-side dielectric material layers 760 embedding logic-die metal interconnect structures 780 and the logic-side bonding pads 798.

In one embodiment, the through-stack via structure 486 is electrically connected to a semiconductor device 7010 in the logic die 700 through a subset of the memory-side metal interconnect structures (180, 108, 98) and through a subset of the logic-die metal interconnect structures 780. In one embodiment, the semiconductor device comprises an input/output control devices 7010.

In one embodiment shown in FIG. 22A, an end surface of the through-stack via structure 486 is in direct contact with the backside conductive pads 152. In one embodiment, the memory die 900 further comprises at least one source-level material layer 110 that is more distal from an interface between the memory die 900 and the logic die 700 than a most distal layer of the alternating stacks (32, 46) is from the interface; the at least one source-level material layer 110 electrically contacts sidewalls of the vertical semiconductor channels 60; and the through-stack via structure 486 vertically extends through an opening in the at least one source-level material layers 110, and is electrically isolated from the at least one source-level material layers110.

In one embodiment, the memory die 900 further comprises a backside dielectric layer 106 that is more distal from the interface than the at least one source-level material layer 110 is from the interface, wherein the through-stack via structure 486 vertically extends through an openings in the backside dielectric layer 106.

In one embodiment, the memory die 900 further comprises a conductive source layer 122 that is more distal from the interface than the backside dielectric layer 106 is from the interface, wherein the backside conductive pad 152 is located within an opening in the conductive source layer 122. In one embodiment, the conductive source layer 122 and the backside conductive pad 152 have a same material composition and a same thickness.

In one embodiment, the memory die 900 further comprises a backside passivation layer (124, 125) covering the conductive source layer 122 and having an opening that overlies the backside conductive pad 152; and the backside conductive pad 152 comprises a solder bonding pad including a layer stack comprising a copper layer, a diffusion barrier layer, and an under-bump metallization layer.

In one embodiment shown in FIG. 23A, the memory die 900 further comprises: a bonding-level dielectric layer 126 overlying the conductive source layer 122 and the backside conductive pad 152; and a backside bonding pad 158 embedded in the bonding-level dielectric layer 126 and electrically connected the the backside conductive pad 152, wherein the backside bonding pad 158 is configured for metal-to-metal bonding and has a physically exposed copper surface.

In one embodiment, the peripheral circuit 720 comprises: word line drivers 70W configured to drive a subset of the electrically conductive layers 46 within the alternating stacks (32, 46); bit line drivers 70B configured to drive bit lines 108 that are located in the memory die 900 and electrically connected to first ends of a respective subset of the memory stack structures 55; and a source line driver 70S configured to drive a source layer (such as a conductive source layer 122) that is located in the memory die 900 and electrically connected to second ends of a respective plurality of the memory stack structures 55.

In one embodiment, the vertically-extending opening 489 is entirely laterally surrounded the alternating stacks (32, 46) such that an entirety of the vertically-extending opening 489 is located within an area of the alternating stack (32, 46) in the plan view. In one embodiment, the through-stack via structure 486 is laterally spaced from a sidewall of the vertically-extending opening 489 by a tubular dielectric spacer 484. In one embodiment, a sidewall of the through-stack via structure 486 is tapered relative to a vertical direction that is perpendicular to an interface between the memory die 900 and the logic die 700 such that the through-stack via structure 486 has a respective variable horizontal cross-sectional area that decreases with a vertical distance from a horizontal plane including the interface.

The centralized input/output pads 152 and the through-stack via structures 486 of the embodiments of the present disclosure can reduce chip size and increase memory array density, facilitate vertical stacking of multiple memory dies, and provide enhanced high-speed performance.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A bonded assembly, comprising:
a memory die comprising:
an alternating stack of insulating layers and electrically conductive layers;
memory-side dielectric material layers embedding memory-side metal interconnect structures and memory-side bonding pads;
memory stack structures each comprising a memory film and a vertical semiconductor channel vertically extending through the alternating stack in a memory array region;
layer contact via structures contacting a respective electrically conductive layer within the alternating stack in a contact region;
a through-stack via structure vertically extending through a vertically-extending opening in the alternating stack within a center region of the memory die, which comprises a volume within the memory die that is more proximal to a geometrical center of the memory die than to a periphery of the memory die defined by outer sidewalls of the memory die in a plan view along a vertical direction; and
a backside conductive pad electrically contacting the through-stack via structure; and
a logic die comprising a peripheral circuit and logic-side bonding pads which are bonded to the memory-side bonding pads.

2. The bonded assembly of claim 1, wherein the logic die further comprises logic-side dielectric material layers embedding logic-die metal interconnect structures and the logic-side bonding pads.

3. The bonded assembly of claim 2, wherein the through-stack via structure is electrically connected to a semiconductor device in the logic die through a subset of the memory-side metal interconnect structures and through a subset of the logic-die metal interconnect structures.

4. The bonded assembly of claim 3, wherein the semiconductor device in the logic die comprises an input/output control device.

5. The bonded assembly of claim 1, wherein an end surface of the through-stack via structure is in direct contact with the backside conductive pad.

6. The bonded assembly of claim 1, wherein:
the memory die further comprises at least one source-level material layer that is more distal from an interface between the memory die and the logic die than a most distal layer of the alternating stacks is from the interface;
the at least one source-level material layer electrically contacts sidewalls of the vertical semiconductor channels; and
the through-stack via structure vertically extends through an opening in the at least one source-level material layer, and is electrically isolated from the at least one source-level material layer.

7. The bonded assembly of claim 6, wherein the memory die further comprises a backside dielectric layer that is more distal from the interface than the at least one source-level material layer is from the interface, and wherein the through-stack via structure vertically extends through an opening in the backside dielectric layer.

8. The bonded assembly of claim 7, wherein the memory die further comprises a conductive source layer that is more distal from the interface than the backside dielectric layer is from the interface, and wherein the backside conductive pad is located within an opening in the conductive source layer.

9. The bonded assembly of claim 8, wherein the conductive source layer and the backside conductive pad have a same material composition and a same thickness.

10. The bonded assembly of claim 8, wherein:
the memory die further comprises a backside passivation layer covering the conductive source layer and having an opening that overlies the backside conductive pad; and
the backside conductive pad comprises a solder bonding pad including a layer stack comprising a copper layer, a diffusion barrier layer, and an under-bump metallization layer.

11. The bonded assembly of claim 8, wherein the memory die further comprises:
a bonding-level dielectric layer overlying the conductive source layer and the backside conductive pad; and
a backside bonding pad embedded in the bonding-level dielectric layer and electrically connected the backside conductive pads wherein the backside bonding pad is configured for metal-to-metal bonding and has a physically exposed copper surface.

12. The bonded assembly of claim 1, wherein the peripheral circuit comprises:
word line drivers configured to drive a subset of the electrically conductive layers within the alternating stacks;
bit line drivers configured to drive bit lines that are located in the memory die and electrically connected to first ends of a respective subset of the memory stack structures; and
a source line driver configured to drive a conductive source layer that is located in the memory die and electrically connected to second ends of a respective plurality of the memory stack structures.

13. The bonded assembly of claim 1, wherein the vertically-extending opening is entirely laterally surrounded by the alternating stack such that an entirety of the vertically-extending opening is located within an area of the alternating stack in the plan view.

14. The bonded assembly of claim 1, wherein the through-stack via structure is laterally spaced from a sidewall of the vertically-extending opening by a tubular dielectric spacer.

15. The bonded assembly of claim 1, wherein a sidewall of the through-stack via structure is tapered relative to a vertical direction that is perpendicular to an interface between the memory die and the logic die such that the through-stack via structure has a respective variable horizontal cross-sectional area that decreases with a vertical distance from a horizontal plane including the interface.

16. A method of forming a bonded assembly, comprising:
forming an alternating stack of insulating layers and electrically conductive layers over a carrier substrate;
forming memory openings vertically extending through the alternating stack;
forming memory stack structures in the memory openings, wherein each of the memory stack structures comprises a memory film and vertical semiconductor channel;
forming a vertically-extending opening through the alternating stack;
forming a through-stack via structure in the vertically-extending opening;
forming memory-side dielectric material layers embedding memory-side metal interconnect structures and memory-side bonding pads over the alternating stack and the through-stack via structure form a memory die;
providing a logic die which comprises peripheral circuit and logic-side bonding pads;
bonding the logic-side bonding pads to the memory-side bonding pads;
detaching the carrier substrate from an assembly comprising the memory die and the logic die to expose the through-stack via structure; and
forming a backside conductive pad that is electrically connected to the through-stack via structure.

17. The method of claim 16, wherein the through-stack via structure is formed in a center region of the memory die which comprises a volume within the memory die that is more proximal to a geometrical center of the memory die than to a periphery of the memory die defined by outer sidewalls of the memory die in a plan view along a vertical direction.

18. The method of claim 16, wherein the through-stack via structure is electrically connected to a semiconductor device in the logic die through a subset of the memory-side metal interconnect structures and through a subset of logic-die metal interconnect structures in the logic die.

19. The method of claim 18, wherein the semiconductor device comprises an input/output control device.

20. The method of claim 16, further comprising depositing and patterning a backside conductive layer over end portions of the memory stack structures that are distal from an interface between the memory die and the logic die, wherein a patterned portion of the backside conductive layer comprises a conductive source layer that is electrically connected to the end portions of the memory stack structures, and an additional patterned portion of the backside conductive layer comprise the backside conductive pad.
